(19) United States
(12) Patent Application Publication
(10) Pub. No.: US 2024/0405169 A1
(43) Pub. Date: Dec. 5, 2024

(54) WAVELENGTH CONVERSION UNIT ARRANGEMENT AND METHOD OF USING THE SAME

(71) Applicant: EPISTAR CORPORATION, Hsinchu (TW)

(72) Inventors: Chong-Yu WANG, Hsinchu (TW); Wei-Shan HU, Hsinchu City (TW); Ching-Tai CHENG, Hsinchu (TW); Chien-Chih CHEN, Hsinchu (TW); Min-Hsun HSIEH, Hsinchu (TW)

(21) Appl. No.: 18/675,532

(22) Filed: May 28, 2024

Related U.S. Application Data
(60) Provisional application No. 63/556,338, filed on Feb. 21, 2024.
(60) Provisional application No. 63/471,078, filed on Jun. 5, 2023.

(30) Foreign Application Priority Data
Jun. 5, 2023 (TW) 112120911
Apr. 8, 2024 (TW) 113112956
May 17, 2024 (TW) 113118415

(51) Int. Cl. H01L 33/50; H01L 25/16

(52) U.S. Cl. CPC H01L 33/505; H01L 25/167; H01L 2933/0041

(57) ABSTRACT

A wavelength conversion unit arrangement includes a carrier and a wavelength conversion unit. The wavelength conversion unit includes a wavelength conversion layer and a filter layer, and the filter layer attaches the wavelength conversion unit to the carrier. The filter layer has a first surface facing the carrier and a second surface opposite the first surface, and the first surface and the second surface have different textures.

### CROSS-REFERENCE TO RELATED APPLICATIONS

This application claims priority to, and the benefit of, U.S. Provisional Application Ser. No. 63/471,078 filed on Jun. 5, 2023, U.S. Provisional Application Ser. No. 63/556,338 filed on Feb. 21, 2024, Taiwan Patent Application No. 112120911 filed on Jun. 5, 2023, Taiwan Patent Application No. 113112956 filed on Apr. 8, 2024, and Taiwan Patent Application No. 113118415 filed on May 17, 2024, the entire contents of which are hereby incorporated by reference herein in their entireties.

### TECHNICAL FIELD

The present disclosure relates to a wavelength conversion unit arrangement and the method of using the same.

### DESCRIPTION OF BACKGROUND ART

The light-emitting diode (LED) is an optoelectronic semiconductor component which has many advantages, such as low power consumption, low heat generation, long operating life, high impact resistance, small size, and fast reaction speed. Therefore, it is widely used in many fields such as lighting fixtures and display devices.

A quantum dot film can be used to improve the color gamut performance of the display device. For example, the quantum dot film can be used to convert blue light generated from the LED into red light or green light. However, the production cost of the quantum dot film is expensive, so how to improve the application efficiency of the quantum dot film will greatly affect the production cost of the display device.

### SUMMARY OF THE APPLICATION

The present disclosure provides a method for manufacturing a quantum dot film, and a light-emitting component using the quantum dot film as a wavelength conversion unit, to reduce manufacturing costs and process time.

According to one embodiment of the present disclosure, a wavelength conversion unit arrangement is disclosed. The wavelength conversion unit arrangement includes a carrier and a wavelength conversion unit. The wavelength conversion unit includes a first wavelength conversion layer and a filter layer, and the filter layer attaches the wavelength conversion unit on the carrier. The filter layer has a first surface facing the carrier and a second surface facing away from the carrier, wherein the first surface and the second surface have different textures.

### BRIEF DESCRIPTION OF THE DRAWINGS

The embodiments of the present disclosure may be more fully understood by reading the subsequent detailed description and examples with references made to the accompanying drawings. In addition, for clarity, the features in the drawings may not be drawn to actual scale, so some features in some drawings may be deliberately enlarged or reduced in size, wherein:

FIGS. 1A and 1B illustrate a cross-sectional view of a pixel module in accordance with one embodiment of the present disclosure.

FIGS. 2A-2G illustrate a manufacturing process of a red sub-pixel as shown in FIG. 1A.

FIGS. 3A-3D illustrate a manufacturing process of a red sub-pixel as shown in FIG. 1B.

FIG. 3E illustrates a cross-sectional view of light-emitting component arrangement in accordance with one embodiment of the present disclosure.

FIG. 4 illustrates a schematic diagram of transferring a wavelength conversion unit to a light-emitting element accordance with one embodiment of the present disclosure.

FIGS. 5A-5C illustrate a manufacturing process of a light-emitting component as shown in FIG. 4.

FIGS. 6A-6C illustrate a manufacturing process of a wavelength conversion unit arrangement as shown in FIG. 4.

FIGS. 7A and 7B illustrate schematic diagrams of a surface profile of a wavelength conversion unit in accordance with one embodiment of the present disclosure.

FIGS. 8A and 8B illustrate a manufacturing process of transferring a wavelength conversion unit to a light-emitting element in accordance with different embodiments of the present disclosure.

FIG. 9 illustrates a manufacturing process of transferring a wavelength conversion unit to a light-emitting element in accordance with one embodiment of the present disclosure.

FIG. 10 illustrates a cross-sectional view of a wavelength conversion unit arrangement as shown in FIG. 9.

FIGS. 11A, 11B, and 12 illustrate a cross-sectional view of a pixel module in accordance with different embodiments of the present disclosure.

FIGS. 13A-13C illustrate a manufacturing process of a pixel module as shown in FIG. 12.

FIG. 14 illustrate a schematic diagram of a monolithic array chip in accordance with one embodiment of the present disclosure.

FIGS. 15A and 15B illustrate schematic diagrams of positions of light-emitting bodies and a wavelength conversion unit in a pixel in accordance with one embodiment of the present disclosure.

FIG. 16 illustrates a cross-sectional view of a pixel module in accordance with one embodiment of the present disclosure.

FIGS. 17A, 17B, 18A, and 18B illustrate schematic diagrams of positions of light-emitting bodies and a wavelength conversion unit in a pixel in accordance with different embodiments of the present disclosure.

FIG. 19 illustrates a cross-sectional view of a pixel module in accordance with one embodiment of the present disclosure.

FIGS. 20A-20G illustrate a manufacturing process of an optical set in accordance with one embodiment of the present disclosure.

FIG. 21 illustrates a manufacturing process of transferring an optical set to a monolithic array chip in accordance with one embodiment of the present disclosure.

FIGS. 22-24 illustrate exploded views of a monolithic array chip and two structural layers of an optical set in accordance with different embodiments of the present disclosure.

FIG. 25 illustrates a cross-sectional view of a pixel module in accordance with one embodiment of the present disclosure.

FIGS. 26A-26G illustrate a manufacturing process of a light-emitting element in accordance with one embodiment of the present disclosure.

### DETAILED DESCRIPTION OF THE APPLICATION

The embodiments of the present disclosure will be described in detail below with reference to the accompanying drawings, so that those skilled in the art to which the present disclosure belongs can fully understand the spirit of the present disclosure. The present disclosure is not limited to the following embodiments, but may be implemented in other forms. In this specification, there are some same reference numerals, indicating components with the same or similar structure, function and principle. For simplicity of description, components with the same reference numerals will not be described again.

The present disclosure provides a manufacturing method of a wavelength conversion unit and a light-emitting component using the wavelength conversion unit to reduce manufacturing costs and process time. In the present disclosure, an LED chip is used as a light source in a light-emitting element.

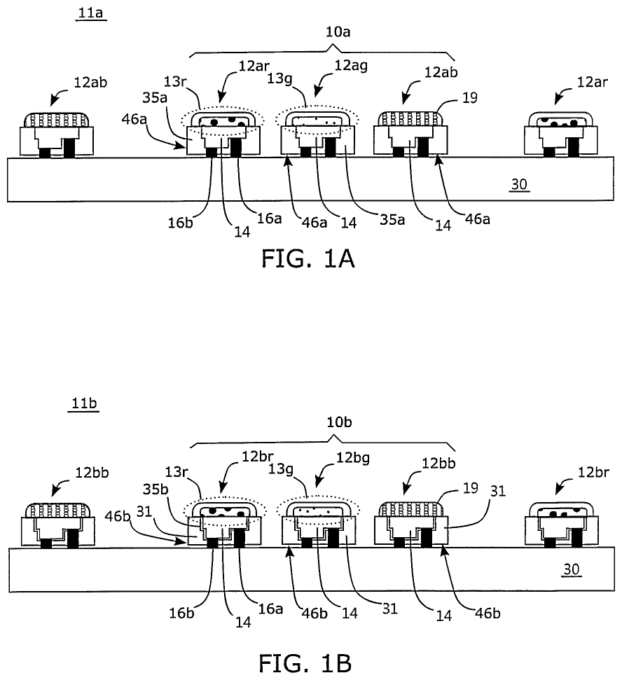

FIG. 1A illustrates a cross-sectional view of a pixel module 11a in accordance with one embodiment of the present disclosure. The pixel module 11a includes a plurality of pixels 10a arranged in an array and arranged on a driving carrier 30. The driving carrier 30 includes a print circuit board (PCB) or a glass substrate with thin film transistors (TFTs). One of the plurality of pixels 10a includes three sub-pixels: a red sub-pixel 12ar, a green sub-pixel 12ag, and a blue sub-pixel 12ab, which can be driven by circuits on the driving carrier 30 to generate red light, green light and blue light respectively. In one embodiment, the pixel module can be used as a display panel in a display device.

The red sub-pixel 12ar includes a light-emitting element 46a and a wavelength conversion unit 13r. The light-emitting element 46a includes an LED chip 14 and a light reflecting layer 35a. The LED chip 14 is electrically connected to the driving carrier 30 through two electrodes 16a, 16b, and emits light, such as blue light and/or ultraviolet light, driven by circuits. The light reflecting layer 35a surrounds and covers sidewall of the LED chip 14 to reflect the light emitted from the sidewall of the LED chip 14 and enhance the intensity of the light emitted upward from the LED chip 14. The wavelength conversion unit 13r includes a wavelength conversion layer and a filter layer stacked on each other. The wavelength conversion layer can convert the light emitted from the LED chip 14 into red light, and the filter layer can block the light emitted from the LED chip 14 whose wavelength has not been converted by the wavelength conversion layer.

Similar to the red sub-pixel 12ar, the green sub-pixel 12ag includes the light-emitting element 46a and a wavelength conversion unit 13g. The wavelength conversion unit 13g includes a wavelength conversion layer and a filter layer stacked on each other. The wavelength conversion unit 13g can convert the light emitted from the LED chip 14 into green light and prevent the leakage of the light whose wavelength has not been converted by the wavelength conversion unit 13g from the green sub-pixel 12ag.

The blue sub-pixel 12ab includes the light-emitting element 46a and a filter layer 19. The filter layer 19 can filter shorter wavelength part of the light generated from the LED chip 14 (such as filter ultraviolet light from blue light) of the sub-pixel 12ab. That is to say, the filter layer 19 can improve the color purity of the light emitted by the blue sub-pixel.

FIG. 1B illustrates a cross-sectional view of a pixel module 11b in accordance with another embodiment of the present disclosure. The pixel module 11b includes a plurality of pixels 10b arranged in an array and arranged on the driving carrier 30. The pixel 10b includes a red sub-pixel 12br, a green sub-pixel 12bg, a blue sub-pixel 12bb. The detailed description of the pixel 10b in FIG. 1B can be referred to the pixel 10a in FIG. 1A and corresponding descriptions.

The red sub-pixel 12br includes a light-emitting element 46b and the wavelength conversion unit 13r. The light-emitting element 46b includes the LED chip 14, a light reflecting layer 35b and a surrounding portion 31. The green sub-pixel 12bg and the blue sub-pixel 12bb shown in FIG. 1B also includes the light reflecting layer 35b and the surrounding portion 31. The light reflecting layer 35b has an outer contour substantially conformal to that of the LED chip 14 and is formed on the sidewall and bottom surface of the LED chip 14 with exposing a portion of the electrodes 16a and 16b. The light reflecting layer 35b can reflect the light emitted from the sidewall of the LED chip 14 to enhance the intensity of the light emitted upward by the LED chip 14. The surrounding portion 31 surrounds the LED chip 14 and the light reflecting layer 35b. As shown in FIG. 1B, the surrounding portion 31 has a rectangular outer contour and covers the sidewall and bottom surface of the light reflecting layer 35b. Compared with the light reflecting layer 35b, the surrounding portion 31 has poorer reflectivity for the light emitted by the LED chip 14. In different embodiments, the surrounding portion 31 has translucent, semi-translucent, or opaque properties, and has white, gray or black appearance.

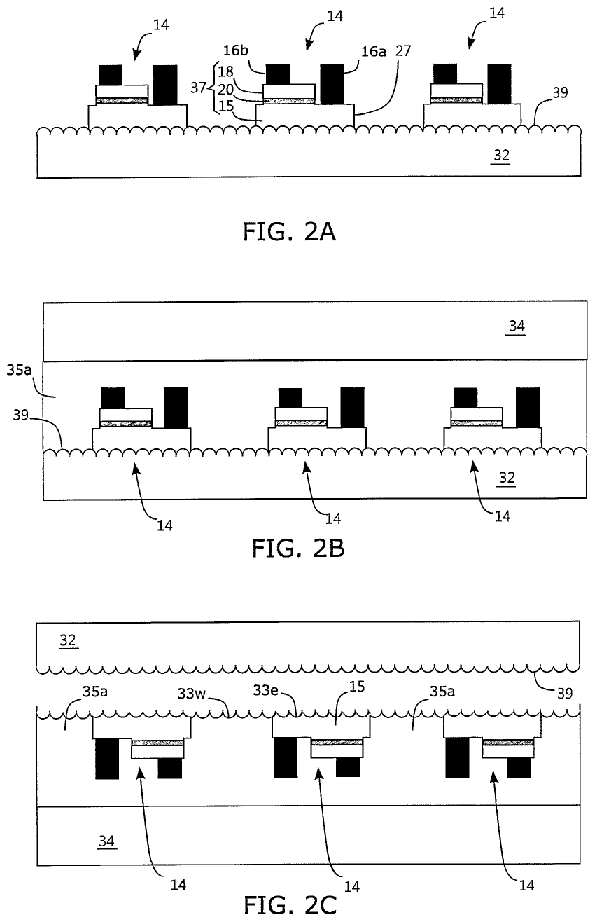

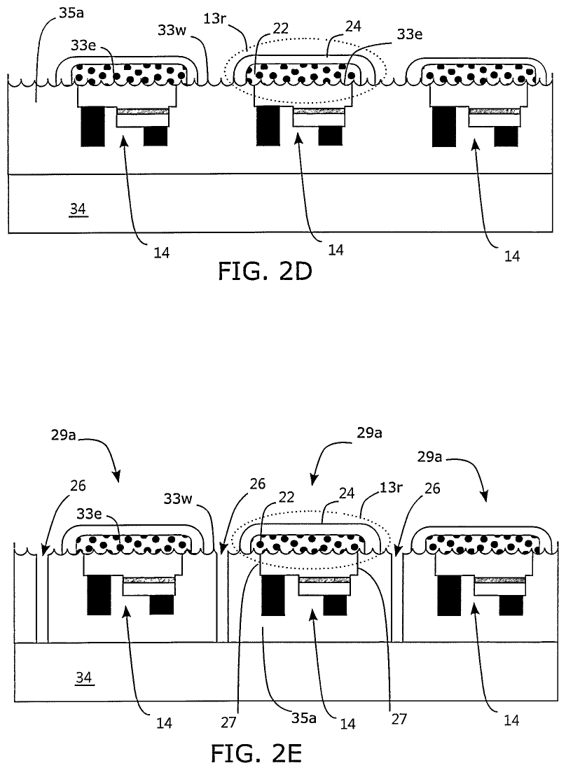

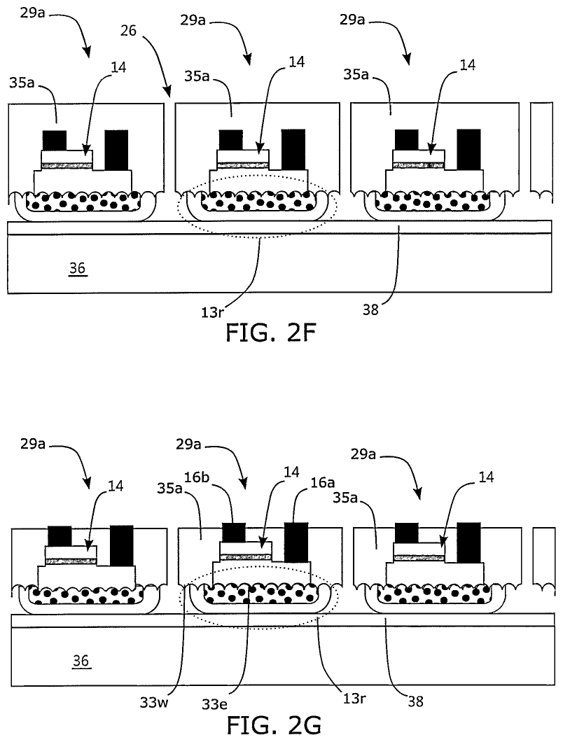

FIGS. 2A-2G illustrate a manufacturing process of a red sub-pixel as shown in FIG. 1B. As shown in FIG. 2A, a plurality of LED chips 14 is formed on a growth substrate 32. In one embodiment, the growth substrate 32 is a sapphire substrate which has a patterned surface 39. In other words, the growth substrate 32 can be a patterned sapphire substrate (PSS). The LED chip 14 includes a semiconductor stack 37 which includes a first semiconductor layer 15, a second semiconductor layer 18, and an active layer 20 located between the first semiconductor layer 15 and the second semiconductor layer 18. In one embodiment, the first semiconductor layer 15 and the second semiconductor layer 18 have different polarities, such as an n-type semiconductor layer and a p-type semiconductor layer, respectively. In one embodiment, the first semiconductor layer 15, the active layer 20, and the second semiconductor layer 18 are sequentially and epitaxially stacked on the growth substrate 32. Through multiple photolithography and etching processes, a plurality of semiconductor stacks 37 is separated formed on the growth substrate 32. Then, two electrodes 16a, 16b are formed on the semiconductor layers 15, 18 respectively to form the LED chip 14, as shown in FIG. 2A. As shown in FIG. 2A, the sidewalls of the semiconductor layers 15 and 18 are substantially parallel to the sidewall of the growth substrate 32. In other embodiments, the sidewalls of semiconductor layers 15 and/or 18 are not parallel to the sidewall of the growth substrate 32. For example, in a cross-sectional view, the second semiconductor layer 18 has a trapezoidal outer contour (not shown).

As shown in FIG. 2B, the light reflecting layer 35a is laminated between the growth substrate 32 and a carrier 34. The light reflecting layer 35a is filled between the plurality of LED chips 14 and covers the electrodes 16a, 16b of the LED chips 14. In one embodiment, the light reflecting layer 35a is a semi-solid (B-stage) adhesive film that adhesives and covers the growth substrate 32 and the LED chip 14. By controlling the operating temperature and/or vacuum value during lamination process, the light reflecting layer 35a can be filled into the microstructures on the patterned surface 39.

As shown in FIG. 2C, in one embodiment, a laser lift-off (LLO) process is used to separate the LED chips 14 and the light reflecting layer 35a from the growth substrate 32. Since the texture of the microstructures on the patterned surface 39 is copied to the surfaces of the first semiconductor layer 15 and the light reflecting layer 35a, a light-exiting surface 33e of the LED chip 14 and an upper surface 33w of the light reflecting layer 35a have corresponding texture after being separated from the growth substrate 32. The light-exiting surface 33e is substantially coplanar with the upper surface 33w and has continuous textures extending to the upper surface 33w.

In other embodiments, the light reflecting layer 35a is formed on the growth substrate 32 and between two adjacent LED chips 14 by printing, coating, spraying, dispensing or molding process. Through an adhesive layer (not shown) on the carrier 34 and a separation process, the LED chips 14 can be transferred from the growth substrate 32 to the carrier 34.

The light reflecting layer 35a includes a matrix and a reflective material. The matrix includes silicone resin, epoxy resin, acrylic resin, polyimide (PI) resin, or a mixture thereof. The reflective material includes titanium oxide, zirconium oxide, aluminum oxide, zinc oxide, barium sulfate, calcium carbonate, or mixtures thereof. In one embodiment, the light reflecting layer 35a has a white appearance to increase light reflectivity.

The carrier 34 can be a soft substrate or a rigid substrate. The soft substrate can be a flexible polymer substrate, and the rigid substrate can be a glass substrate or a sapphire substrate.

As shown in FIG. 2D, a wavelength conversion unit 13r is formed on the light-exiting surface 33e of the LED chip 14. In one embodiment, a precursor of a wavelength conversion layer 22 is first coated on the light-exiting surface 33e and the upper surface 33w, and then a photolithography process is used to form a wavelength conversion layer 22. A filter layer 24 is then formed on the wavelength conversion layer 22 by coating and photolithography processes. The wavelength conversion layer 22 covers the light-exiting surface 33e, and the filter layer 24 covers the wavelength conversion layer 22.

In one embodiment, the wavelength conversion layer 22 includes quantum dot material for converting the light emitted by the LED chip 14 (such as blue light or ultraviolet light) into the light with another wavelength (such as red light). In one embodiment, the quantum dot material includes CdS. The choice of quantum dot materials is not limited thereto. Any quantum dot material suitable for the application can be used. For example, the quantum dot material includes one of the following or a mixture thereof: CdSe, CdTe, ZnO, ZnS, ZnSe, ZnTe, GaAs, GaP, GaSb, HgS, HgSe, HgTe, InAs, InP, InSb, AlAs, AlP, CuInS, CuInSe, AlSb.

The filter layer 24 can filter the light emitted by the wavelength conversion layer 22 or the LED chip 14. In one embodiment, the filter layer 24 is a red filter, which allows light in the red wavelength range to pass through but blocks light in other wavelength ranges from passing through. In another embodiment, the filter layer 24 includes an ultraviolet light absorbing layer for absorbing light in the ultraviolet wavelength band and transmitting light in other wavelength bands (such as visible light).

A portion of the light reflecting layer 35a is removed to form a plurality of light-emitting components 29a separately on the carrier 34, as shown in FIG. 2E. One of the light-emitting components 29a includes the LED chip 14, the light reflecting layer 35a, and the wavelength conversion unit 13r. In one embodiment, after forming a patterned mask on the light reflecting layer 35a, an inductively coupled plasma (ICP) process is used to etch a portion of the light reflecting layer 35a to form an isolation channel 26. In another embodiment, a laser cutting process is used to directly remove a portion of the light reflecting layer 35a to form the isolation channel 26. The isolation channel 26 does not directly contact the LED chip 14, so that the light-emitting component 29a includes a portion of the upper surface 33w, and the wavelength conversion unit 13r covers the light-exiting surface 33e and a portion of the upper surface 33w. The sidewall 27 of the LED chip 14 is surrounded by the light reflecting layer 35a. As shown in FIG. 2E, the sidewall 27 is substantially perpendicular to the light-exiting surface 33e. In other embodiments, the sidewall 27 is not perpendicular to the light-exiting surface 33e.

FIG. 2F shows a cross-sectional view of the step of attaching the light-emitting component 29a on a carrier 36 through an adhesive layer 38. In one embodiment, the carrier 36 and the carrier 34 are made of the same material. For example, both of the carrier 34, 36 are sapphire substrate. In one embodiment, only a part of the plurality of light-emitting components 29a is transferred from the carrier 34 to the carrier 36, so that the other part of the light-emitting components 29a (such as light-emitting components whose luminous wavelength, luminous intensity, or other optical and/or characteristics do not meet requirements) remains on the carrier 34. For example, the structure shown in FIG. 2E is inverted, and a plurality of light-emitting components 29a is attached to the carrier 36 through an adhesive layer 38. Next, a laser light penetrates the carrier 34 and selectively irradiates the light-emitting component 29a on the carrier 36. The light reflecting layer 35a of the light-emitting component 29a can be removed (such as be decomposed) after being irradiated by the laser light with appropriate wavelength and/or energy to reduce the adhesive force between the light reflecting layer 35a and carrier 34. When the adhesive force between the light-emitting component 29a and the carrier 34 is less than that between the light-emitting component 29a and the carrier 36, the light-emitting component 29a can be transferred to the carrier 36.

FIG. 2G shows a cross-sectional view of the step of thinning the light reflecting layer 35a as shown in FIG. 2F. In one embodiment, the light reflecting layer 35a is thinned by a dry etching process (such as ICP process) until the electrodes 16a, 16b are exposed. In one embodiment, the light-emitting component 29a in FIG. 2G can be transferred to the driving carrier 30 and then the electrodes 16a, 16b are electrically connected to the driving carrier 30, to serve as a red sub-pixel 12ar shown in FIG. 1A. In one embodiment, the light-emitting component 29a shown in FIG. 2G can be used in the pixel module to replace the light-emitting element 46a and the wavelength conversion unit 13r shown in FIG. 1A.

A light-emitting component arrangement is also provided in FIG. 2G, wherein a plurality of light-emitting components 29a is respectively arranged on the carrier 36. One of the light-emitting components 29a includes the LED chip 14, the light reflecting layer 35a and the wavelength conversion unit 13r. Two electrodes 16a, 16b in the LED chip 14 can electrically connect to a driving carrier 30 as shown in FIG. 1A. The light-exiting surface 33e of the LED chip 14 has the same or similar texture as the upper surface 33w of the light reflecting layer 35a, and the texture extends from the light-exiting surface 33e to the upper surface 33w.

In one embodiment, the green sub-pixel 12ag shown in FIG. 1A can be manufactured by using the aforementioned manufacturing process of the red sub-pixel 12ar, but the wavelength conversion layer 22 in FIGS. 2D-2G is replaced by another wavelength conversion layer, wherein properties of the another wavelength conversion layer can be similar to that of the wavelength conversion layer 22 but can convert the light (such as blue light or ultraviolet light) emitted by the LED chip 14 into green light.

In one embodiment, the blue sub-pixel 12ab in FIG. 1A is also manufactured by using a similar manufacturing process as the red sub-pixel 12ar, but the wavelength conversion unit 13r in FIGS. 2D-2G is replaced with a filter layer. This filter layer can be similar to the filter layer 24, but the filter layer in the blue sub-pixel 12ab is used as a blue light filter to only allow light in the blue wavelength band to pass through.

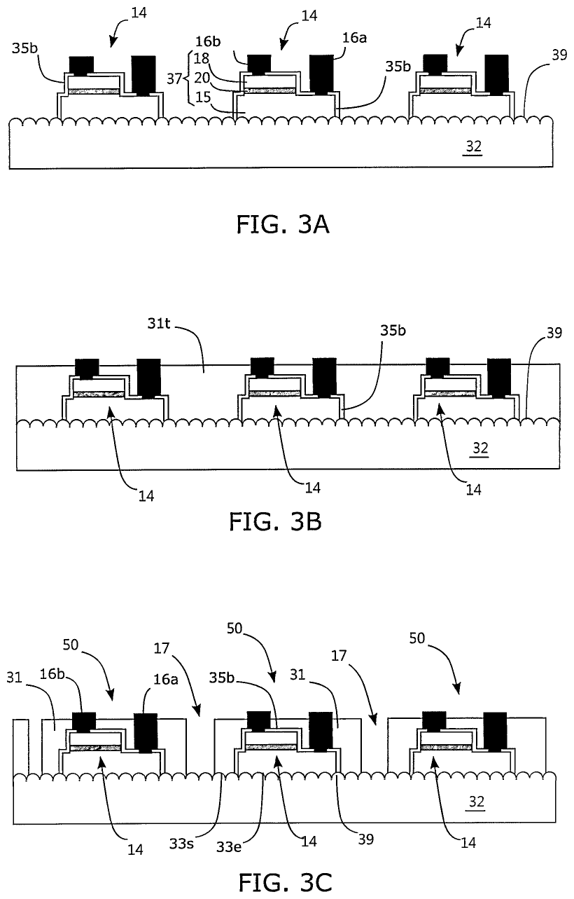

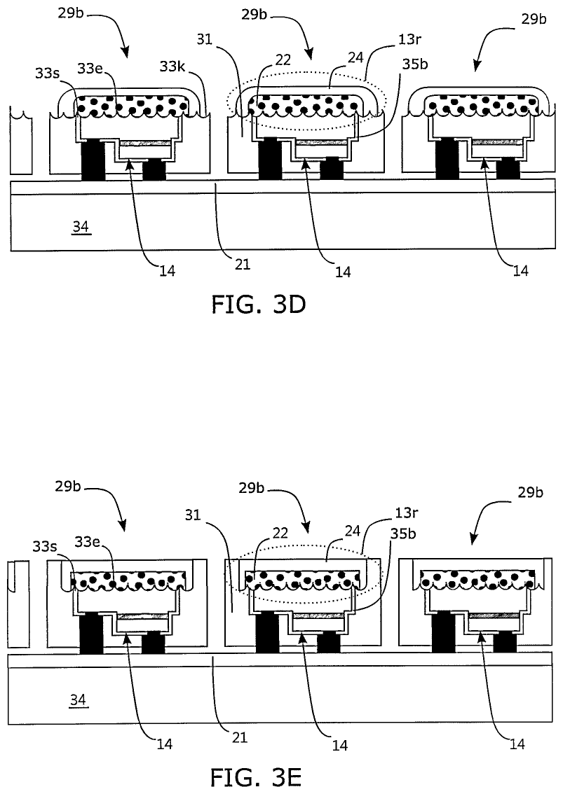

FIGS. 3A-3D illustrate a manufacturing process of the red sub-pixel 12br as shown in FIG. 1B. FIG. 3A shows a cross-sectional view of a step of forming the light reflecting layer 35b on the LED chip 14, wherein the light reflecting layer 35b has an outer contour substantially conformal to that of the semiconductor stack 37. In one embodiment, a temporary light reflecting layer (not shown) is deposited and continuously covers the semiconductor stack 37 and the growth substrate 32 as shown in FIG. 2A, and the thickness of the temporary light reflecting layer on the sidewall 27 of the semiconductor stack 37 is approximately the same as the thickness of the temporary light reflecting layer on the patterned surface 39. Next, a portion of the temporary light reflecting layer is removed through photolithography and etching processes to expose the electrodes 16a, 16b and the patterned surface 39. The remaining temporary light reflecting layer becomes the light reflecting layer 35b as shown in FIG. 3A.

In another embodiment, after forming the semiconductor stack 37 as shown in FIG. 2A, a temporary light reflecting layer is formed to completely cover the semiconductor stack 37 and the patterned surface 39. Then, photolithography and etching processes are used to remove portions of the temporary light reflecting layer to form the light reflecting layer 35b and expose the patterned surface 39 and portions of the semiconductor layers 15, 18. After that, the electrodes 16a, 16b are formed on the expose portions of the semiconductor layers 15, 18 to obtain the structure as shown in FIG. 3A.

The material of the light reflecting layer 35b can be the same as or similar to the material of the light reflecting layer 35a, and both can reflect the light emitted by the LED chip 14. In one embodiment, the light reflecting layer 35b includes a distributed Bragg reflector (DBR).

FIG. 3B shows a cross-sectional view of a step of forming a surrounding layer 31t on the structure shown in FIG. 3A. In one embodiment, a surrounding layer 31t is formed on the growth substrate 32 as shown in FIG. 3A by coating or depositing process. Then, an etching process is used to thin the surrounding layer 31t until the electrodes 16a, 16b are exposed so the structure as shown in FIG. 3B is formed. In another embodiment, the surrounding layer 31t does not completely cover the electrodes 16a, 16b, so the thinning process is not required. In one embodiment, the surrounding layer 31t includes a matrix and a light-absorbing material. The matrix includes silicone resin, epoxy resin, acrylic resin, polyimide resin, or a mixture thereof. The light-absorbing material includes carbon black or other light-absorbing materials. By adjusting the concentration of the light-absorbing material in the matrix, the optical density (OD) value of the surrounding layer 31t can be modified. In another embodiment, the surrounding layer 31t includes a matrix and a reflective material, wherein the material of the surrounding layer 31t can be the same as the material of the aforementioned light reflecting layer 35a.

Next, as shown in FIG. 3C, an isolation channel 17 is formed in the surrounding layer 31t to form a plurality of surrounding portions 31. one surrounding portion 31 surrounds one light-emitting element 50. The detailed description of the manufacturing process of the isolation channel 17 can be referred to the isolation channel 26, FIG. 2E, and the relevant descriptions.

FIG. 3C also shows a light-emitting element arrangement, wherein a plurality of light-emitting elements 50 is separately arranged on the growth substrate 32. The light-emitting element 50 includes an LED chip 14, a light reflecting layer 35b, and a surrounding portion 31. The electrodes 16a, 16b of the LED chip 14 can electrically connect the driving carrier 30 as shown in FIG. 1B. The light-exiting surface 33e of the LED chip 14 and an upper surface 33s of the light reflecting layer 35b have the same or similar texture as the texture of the microstructure on the patterned surface 39 of the growth substrate 32, and the texture on the light-exiting surface 33e extends to the upper surface 33s.

As shown in FIG. 3D, in one embodiment, the light-emitting element 50 as shown in FIG. 3C is transferred to the carrier 34, and the light-exiting surface 33e of the LED chip 14 is covered by the wavelength conversion unit 13r, thereby forming a light-emitting component 29b. In another embodiment, a process similar to the transfer process described in FIG. 2F is performed. The structure shown in FIG. 3C is turned upside down to adhere the light-emitting element 50 to the carrier 34 through an adhesive layer 21, and then the growth substrate 32 and the light-emitting element 50 are separated by a laser lift-off process. Next, the wavelength conversion unit 13r is disposed on the light-exiting surface 33e of the LED chip 14 by using a manufacturing process similar to forming the wavelength conversion unit 13r as described in FIG. 2D and corresponding descriptions. The wavelength conversion unit 13r includes a wavelength conversion layer 22 and a filter layer 24 stacked on each other and completely covers the light-exiting surface 33e of the LED chip 14. As shown in FIG. 3D, an upper surface 33k of the surrounding portion 31, the upper surface 33s of the light reflecting layer 35b, and the light-exiting surface 33e of the LED chip 14 are substantially flush or coplanar with each other. Since the texture of the microstructure on the patterned surface 39 is copied to the LED chip 14, the reflective layer 35b, and the surrounding portion 31, the light-exiting surface 33e, the upper surface 33s, and the upper surface 33k have a corresponding texture, wherein the corresponding texture extends from the light-exiting surface 33e to the upper surface 33s and the upper surface 33k.

In one embodiment, the red sub-pixel 12br shown in FIG. 1B can be replaced by the light-emitting component 29b as shown in FIG. 3D. In one embodiment, the green sub-pixel 12bg in FIG. 1B can be manufactured by using the manufacturing process for forming the red sub-pixel 12br, but the wavelength conversion layer 22 in FIG. 3D is replaced with another wavelength conversion layer which can convert the light (such as blue light or ultraviolet light) emitted by the LED chip 14 into green light. The blue sub-pixel 12bb in FIG. 1B can be manufactured by using a manufacturing process of the red sub-pixel 12br, but the wavelength conversion unit 13r in FIG. 3D is replaced with a filter layer which is set as a blue light filter to allow light in the blue wavelength band to pass through and preventing light in other wavelength bands from passing through.

FIG. 3E shows a light-emitting component arrangement according to an embodiment of the present disclosure. A plurality of light-emitting components 29b is separately arranged on a carrier 34. The light-emitting component 29b includes a wavelength conversion unit 13r, an LED chip 14, a light reflecting layer 35b, and a surrounding portion 31. In one embodiment, the wavelength conversion unit 13r has an approximately rectangular outer contour, and a continuous texture is formed on the bottom surface of the wavelength conversion layer 22 and the bottom surface of the filter layer 24. The surrounding portion 31 covers the sidewall of the wavelength conversion unit 13r, and the upper surface of the surrounding portion 31 is coplanar with the upper surface of the wavelength conversion unit 13r. In one embodiment, the material of the surrounding portion 31 is the same as that of the adhesive layer 21, and the surrounding portion 31 covers the sidewall and the bottom surface of the electrodes (not shown). In another embodiment, no adhesive layer is formed on the carrier 34 (not shown), and the surrounding portion 31 covers the sidewall and the bottom surface of the electrodes and is directly in contact with the carrier 34, so that the LED chip 14 is covered by the surrounding portion 31 and the wavelength conversion unit 13r.

In one embodiment, as the manufacturing process described in FIGS. 2A-2G and 3A-3D and corresponding descriptions, the wavelength conversion unit 13r is first disposed on the light-exiting surface 33e of the LED chip 14, and then the LED chip 14 and the wavelength conversion unit 13r are transferred to the driving carrier 30. In another embodiment, a light source such as the LED chip 14 is first transferred to the driving carrier 30, and then the wavelength conversion unit 13r is transferred to the light-exiting surface 33e of the LED chip 14.

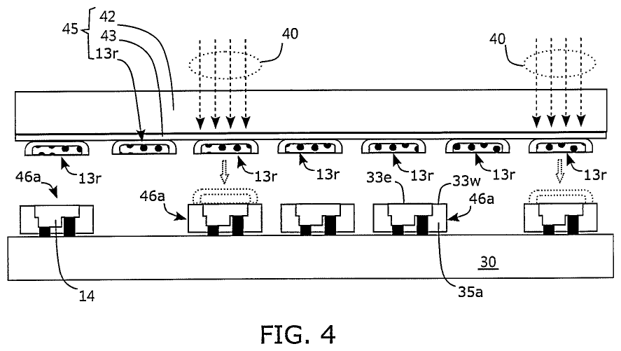

FIG. 4 shows a cross-sectional view of transferring a wavelength conversion unit 13r from a carrier 42 to a light-emitting element 46a on the driving carrier 30. A plurality of light-emitting elements 46a is provided on the driving carrier 30, and a plurality of wavelength conversion units 13r on the carrier 42 can be selectively irradiated by a laser light 40 and then be transferred to the light-emitting elements 46a. In one embodiment, the plurality of wavelength conversion units 13r is connected to the carrier 42 through an adhesive layer 43. The structure of the adhesive layer 43 can be changed after being irradiated by the laser light 40, so that the corresponding wavelength conversion unit 13r can be detached from the carrier 42 and transferred to the light-emitting element 46a to form a red sub-pixel 12ar as shown in FIG. 1A.

In one embodiment, an adhesive layer (not shown) is provided on the light-emitting element 46a shown in FIG. 4 to fix the wavelength conversion unit 13r when the wavelength conversion unit 13r is placed on the light-emitting element 46a. In one embodiment, the adhesive layer is disposed on the light-exiting surface 33e of the LED chip 14 and the upper surface 33w of the light reflecting layer 35a. In one embodiment, the adhesive layer is disposed on the light-exiting surface 33e of the LED chip 14, but not on the upper surface 33w of the light reflecting layer 35a. In one embodiment, the adhesive layer is disposed on the upper surface 33w of the light reflecting layer 35a, but not on the light-exiting surface 33e of the LED chip 14.

In one embodiment, the wavelength conversion unit 13g can be disposed on a carrier first, and then be transferred on the light-emitting element 46a in FIG. 4 to form the green sub-pixel 12ag as shown in FIG. 1A. The filter layer 19 can be disposed on a carrier first, and then be transferred on the light-emitting element 46a in FIG. 4 to form the blue sub-pixel 12ab as shown in FIG. 1A.

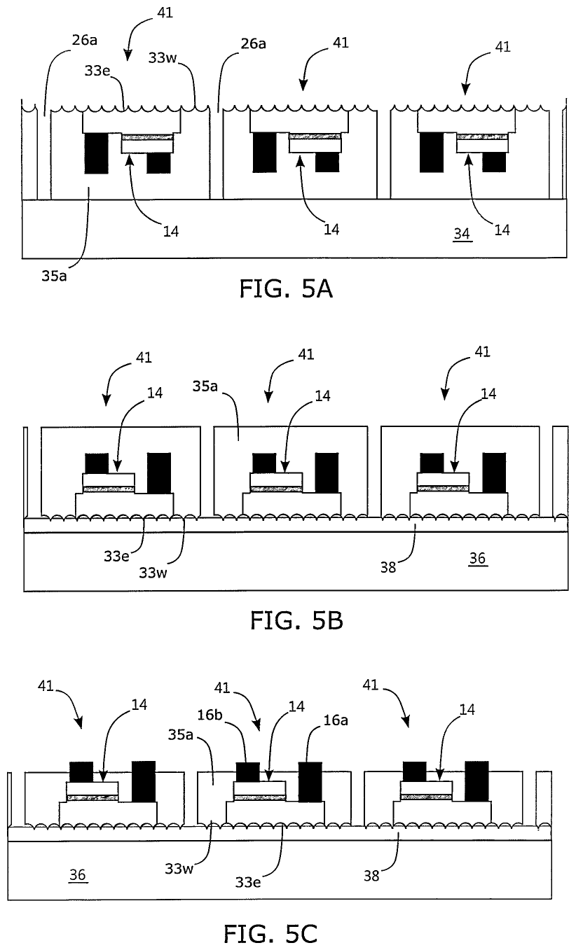

FIGS. 5A-5C show a manufacturing process of the light-emitting element 46a as shown in FIG. 4. In one embodiment, the structure shown in FIG. 5A is formed after the structure shown in FIG. 2C, and a portion of the light reflecting layer 35a is removed to form an isolation channel 26a. The detailed description of a manufacturing process of the isolation channel 26a can be referred to FIG. 2E and the relevant descriptions of the isolation channel 26. The isolation channels 26a separate the plurality of light-emitting elements 41, wherein one light-emitting element 41 includes an LED chip 14.

FIG. 5B shows a cross-sectional view of a step of transferring the light-emitting element 41 shown in FIG. 5A to a carrier 36 through an adhesive layer 38. In one embodiment, the adhesive layer 38 only needs to fix the light-emitting element 41 on the carrier 36, so the adhesive layer 38 does not need to fill or completely fill into the texture on the light-exiting surface 33e and the upper surface 33w, as shown in FIG. 5B.

FIG. 5C shows a cross-sectional view of a step of thinning the thickness of the light reflecting layer 35a of the light-emitting element 41 shown in FIG. 5B. In one embodiment, an etching process is used to thin the thickness of the light reflecting layer 35a until the electrodes 16a, 16b are exposed. In one embodiment, the light-emitting element 41 as shown in FIG. 5C can be further transferred and electrically connected to the driving carrier 30 to serve as a light-emitting element 46a as shown in FIG. 4.

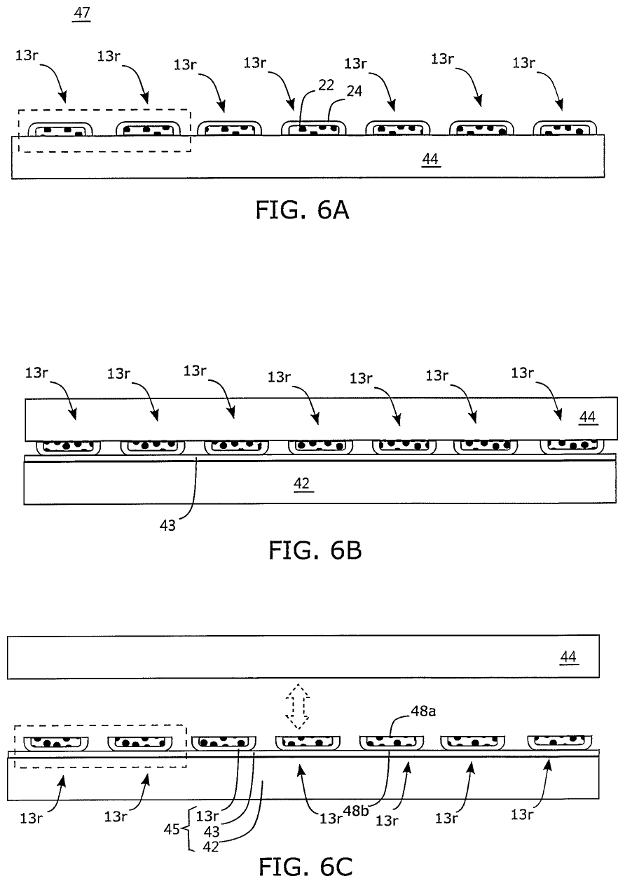

FIGS. 6A to 6C show a manufacturing process to form a wavelength conversion unit 13r as shown in FIG. 4. The wavelength conversion unit 13r, the adhesive layer 43, and the carrier 42 shown in FIG. 4 can be collectively regarded as a wavelength conversion unit arrangement 45. The wavelength conversion unit 13r in the wavelength conversion unit arrangement 45 can be transferred to the light-emitting element 4 shown in FIG. 4 to form the red sub-pixel 12ar shown in FIG. 1A by any transfer process such as a laser transfer process.

As shown in FIG. 6A, the wavelength conversion unit 13r includes a wavelength conversion layer 22 and a filter layer 24, wherein the filter layer 24 completely covers the wavelength conversion layer 22. A carrier 44 can be a sapphire substrate, a quartz substrate, or a glass substrate. In one embodiment, the matrix of the wavelength conversion layer 22 and the matrix of the filter layer 24 are photosensitive materials, such as photoresist. A photolithography process can be used to form a plurality of wavelength conversion layers 22 arranged in an array and arranged on the carrier 44, and then another photolithography process can be used to form a plurality of filter layers 24 on and around the corresponding wavelength conversion layer 22. When the plurality of wavelength conversion units 13r formed on the carrier 44 is very close to each other, a very small amount of material is removed during the photolithography process. In other words, a wavelength conversion unit arrangement 47 shown in FIG. 6A can reduce the material cost of preparing the wavelength conversion unit 13r.

As shown in FIG. 6B, the wavelength conversion unit 13r is adhered to the carrier 42 through the adhesive layer 43, wherein the carrier 42 can be made of sapphire, quartz or glass.

FIG. 6C shows a cross-sectional view of the step of detaching the wavelength conversion unit 13r from the carrier 44. In one embodiment, a laser light with an appropriate wavelength and/or energy is selected to selectively illuminate through the carrier 44 to the wavelength conversion unit 13r located at a specific position. The interfacial structure between the wavelength conversion unit 13r and the carrier 44 can be changed after being irradiated, causing the adhesive force between the wavelength conversion unit 13r and the carrier 44 to be reduced, or even cause the wavelength conversion unit 13r to be separated from the carrier 44. When a distance between the carrier 44 and the carrier 42 increases, the wavelength conversion unit 13r can be fixed on the carrier 42 through an adhesive layer 43 with strong adhesive force to form a wavelength conversion unit arrangement 45. The wavelength conversion unit arrangement 45 includes a wavelength conversion unit 13r, a carrier 42, and an adhesive layer 43 therebetween. In one embodiment, the wavelength conversion unit 13r is transferred to the carrier 42 by increasing the distance between the carrier 44 and the carrier 42 without being irradiated by a laser light when the adhesive force of the wavelength conversion unit 13r to the carrier 44 is less than the adhesive force to the adhesive layer 43. In this disclosure, the wavelength conversion unit arrangement 45 (or the wavelength conversion unit arrangement 47 shown in FIG. 6A) having a plurality of wavelength conversion units 13r is made first, and then the wavelength conversion unit 13r is transferred by a transfer process such as shown in FIG. 4 and corresponding descriptions, which can effectively reduce the manufacturing cost of the wavelength conversion unit 13r.

In another embodiment, the wavelength conversion unit 13r does not contact the carrier 44 and the carrier 42 at the same time, so that the manufacturing step shown in FIG. 6B can be omitted. For example, the carrier 44 in FIG. 6A is first turned upside down, and then the wavelength conversion unit 13r is selectively irradiated with laser light through the carrier 44. The wavelength conversion unit 13r being irradiated is detached from the carrier 44 and transferred to the adhesive layer 43 of the carrier 42. In one embodiment, both the wavelength conversion layer 22 and the filter layer 24 include a material that can be dissociated by laser irradiation to generate gas. For example, both the wavelength conversion layer 22 and the filter layer 24 include acrylic. In other words, when the wavelength conversion unit 13r is irradiated by laser light and separated from the carrier 44, the gas formed by the dissociation of the wavelength conversion unit 13r due to laser irradiation can be released on a surface 48a and to push the wavelength conversion unit 13r towards the carrier 42.

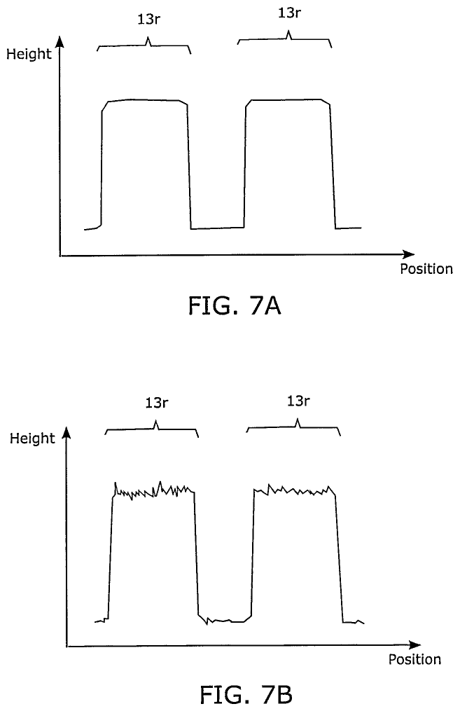

FIG. 7A illustrates a schematic diagram of the surface profile of the exposed surface of two adjacent wavelength conversion units 13r in FIG. 6A. FIG. 7B illustrates a schematic diagram of the surface profile of the exposed surface of two adjacent wavelength conversion units 13r in FIG. 6C. In one embodiment, FIGS. 7A and 7B illustrate schematic diagrams of using a surface profilometer (such as BRUKER's Alpha-Step) to measure the surface heights of two wavelength conversion units 13r to a nearby substrate in the dotted boxes shown in FIGS. 6A and 6C. Compared to a exposed surface of the wavelength conversion unit 13r in FIG. 6A (same as a surface 48b in FIG. 6C), a exposed surface 48a of the wavelength conversion unit 13r in FIG. 6C has a relatively rough surface profile. In other words, the surface 48b dissociated after laser irradiation has a relatively rough profile compared to the surface 48b formed only through exposure and development processes. Therefore, the surface 48b of the wavelength conversion unit 13r facing the carrier 42 and the surface 48a away from the carrier 42 of the wavelength conversion unit 13r shown in FIG. 6C have different textures.

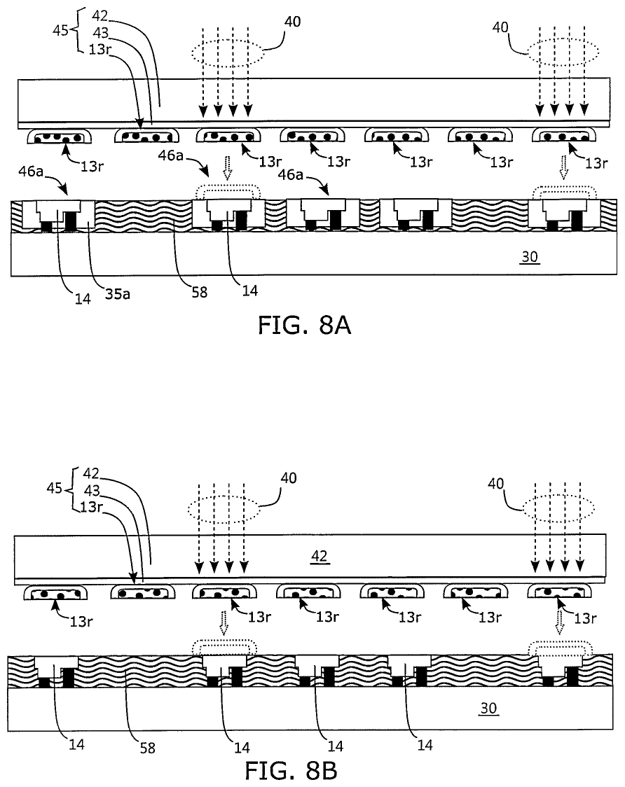

FIGS. 8A and 8B illustrate a manufacturing process of transferring the wavelength conversion unit 13r to the light-emitting element 46a according to one embodiment of the present disclosure. As shown in FIG. 8A, a light-shielding portion 58 is formed on the driving carrier 30 and located between adjacent light-emitting elements 46a. The light-shielding portion 58 can fix the light-emitting element 46a, provide a flat surface that is substantially coplanar with the upper surface of the light-emitting element, and can also prevent crosstalk between two adjacent light-emitting elements 46a. The light-shielding portion 58 includes a matrix and a dark material. The matrix includes silicone resin, epoxy resin, acrylic resin, polyimide resin, or mixture thereof, the dark material includes carbon black or other light-absorbing materials. The optical density value of the light-shielding portion 58 can be modified by adjusting a concentration of the dark material in the matrix. In FIG. 8B, there is no light reflecting layer 35a on the outside of the LED chip 14 as shown in FIG. 8A.

Similarly, the red sub-pixel 12br shown in FIG. 1B can also be formed by transferring the wavelength conversion unit 13r to the light-emitting element 46b arranged on the driving carrier 30. In one embodiment, similar to the light-emitting element 46b shown in FIG. 1B, the light-emitting element 50 in FIG. 3C is first transferred to the driving carrier 30, and then the wavelength conversion unit 13r is transferred to the light-emitting element 50 to form the red sub-pixel 12br shown in FIG. 1B. Similar to the structure shown in FIGS. 8A and 8B, in one embodiment, an additional light-shielding portion can also be provided between the driving carrier 30 and the sub-pixels 12br, 12bg, 12bb as shown in FIG. 1B.

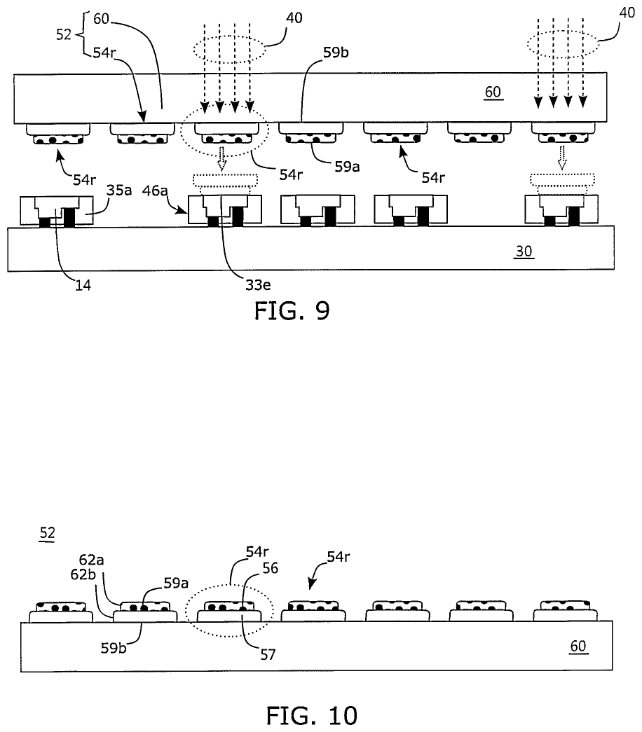

FIG. 9 illustrates a manufacturing process of transferring a wavelength conversion unit 54r from a carrier 60 to the light-emitting element 46a in one embodiment of the present disclosure, and FIG. 10 illustrates a cross-sectional view of a wavelength conversion unit arrangement 52 as shown in FIG. 9. In FIG. 9, the wavelength conversion unit 54r directly contacts the carrier 60 without any adhesive layer therebetween. The wavelength conversion unit arrangement 52 includes a carrier 60 and a wavelength conversion unit 54r formed on the carrier 60. In one embodiment, a filter layer 57 and a wavelength conversion layer 56 are sequentially formed on the carrier 60 through two photolithography processes, wherein the filter layer 57 and the wavelength conversion layer 56 are stacked on each other to form the wavelength conversion unit 54r as shown in FIG. 10. The wavelength conversion unit 54r has a surface 59b facing the carrier 60 and a surface 59a away from the carrier 60. Then, as the process shown in FIG. 9, multiple wavelength conversion units 54r are selectively irradiated through a laser light 40, so that the surface 59b of the wavelength conversion units 54r being irradiated are dissociated and separated from the carrier 60 to cover the light-exiting surface 33e of the LED chip 14. Since the surface 59b of the wavelength conversion unit 54r is a dissociated surface, it becomes rougher than the surface 59a which is not a dissociated surface. In other words, the exposed surface 59a before dissociation and the exposed surface 59b after dissociation have different textures.

In one embodiment, a sub-pixel, such as a red sub-pixel or a green sub-pixel, includes a wavelength conversion unit 54r and a light-emitting element 46a. In a plan view, the filter layer 57 has an edge 62b substantially surrounding the wavelength conversion layer 56, and the wavelength conversion layer 56 has an edge 62a substantially surrounding the light-exiting surface 33e of the LED chip 14. In other words, the filter layer 57 completely covers the wavelength conversion layer 56. In another embodiment, the edge 62a of the wavelength conversion layer 56 is substantially aligned with the edge 62b of the filter layer 57 (not shown), and the wavelength conversion layer 56 and the filter layer 57 have the same edge profile in a plan view. In another embodiment, in a plan view, the edge 62a of the wavelength conversion layer 56 surrounds the filter layer 57 (not shown), and the edge 62b of the filter layer 57 surrounds the light-exiting surface 33e of the LED chip 14 in the light-emitting element 46a.

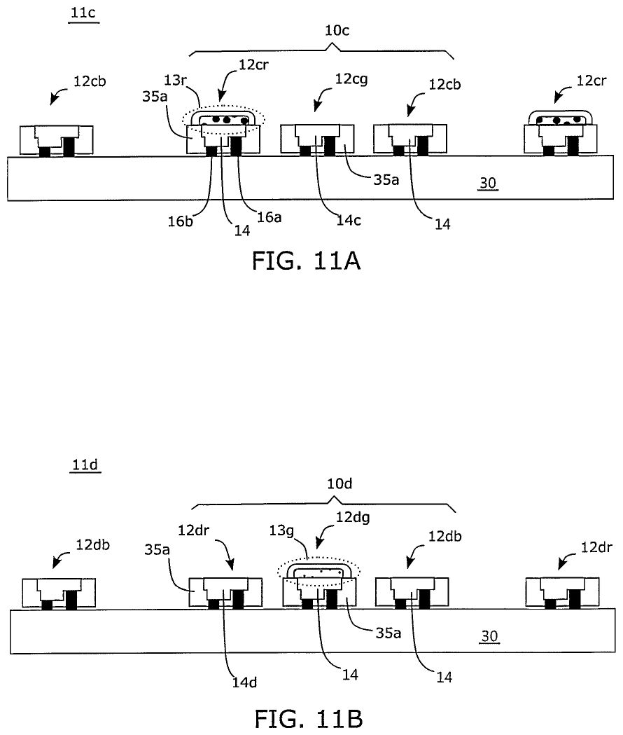

FIGS. 11A and 11B respectively show a pixel module 11c, 11d according to different embodiments of the present disclosure. In some embodiments, all LED chips 14 in a pixel module shown in FIGS. 1A, 1B, 4, 8A, 8B and 9 can emit the same color of light. In other embodiments, different LED chips in a pixel module can emit light of different colors (for example, blue light, green light, and ultraviolet light respectively), and combined with the wavelength conversion unit above them to form different sub-pixels. As shown in FIG. 11A, a pixel 10c includes three sub-pixels (a red sub-pixel 12cr, a green sub-pixel 12cg, and a blue sub-pixel 12cb) driven by circuits on the driving carrier 30 to generate red light, green light, and blue light, respectively. The detailed description of the structure and manufacturing process of the red sub-pixel 12cr in FIG. 11A can be referred to FIG. 1A and the corresponding descriptions of the red sub-pixel 12ar. The LED chip 14 can emit blue light, and the wavelength conversion unit 13r can convert blue light into red light. The blue sub-pixel 12cb shown in FIG. 11A has no filter layer. The green sub-pixel 12cg shown in FIG. 11A has an LED chip 14c that can directly emit green light, so there is no wavelength conversion unit to convert the wavelength of the light emitted by the LED chip 14c.

In FIG. 11B, a red sub-pixel 12dr, a green sub-pixel 12dg, and a blue sub-pixel 12 db of a pixel 10d can be driven by circuits on the driving carrier 30 to generate red light, green light, and blue light, respectively. The detailed description of the structure and manufacturing process of the green sub-pixel 12dg in FIG. 11B can be referred to FIG. 1A and the corresponding descriptions of the green sub-pixel 12ag. The LED chip 14 can emit blue light, and the wavelength conversion unit 13g can convert blue light into green light. The red sub-pixel 12dr in FIG. 11B includes an LED chip 14d that can directly emit red light, so there is no wavelength conversion unit to convert the wavelength of the light emitted by the LED chip 14d.

In other embodiments, the light-emitting component shown in FIGS. 11A and 11B can be modified to have the light reflecting layer 35b and the surrounding portion 31 as shown in FIG. 1B, and a light-shielding portion can also be formed between two adjacent sub-pixels.

In one embodiment, a wavelength conversion unit is first formed on the LED chip 14 as shown in FIGS. 11A, 11B to serve as a sub-pixel, and then be transferred to the driving carrier 30, as disclosed in FIGS. 2A-2G and corresponding descriptions. In other embodiments, the LED chip 14 in FIGS. 11A, 11B can be transferred to the driving carrier 30 first, and then a wavelength conversion unit is formed on the LED chip 14 to serve as a sub-pixel, as disclosed in FIGS. 4, 8A and 8B and corresponding descriptions.

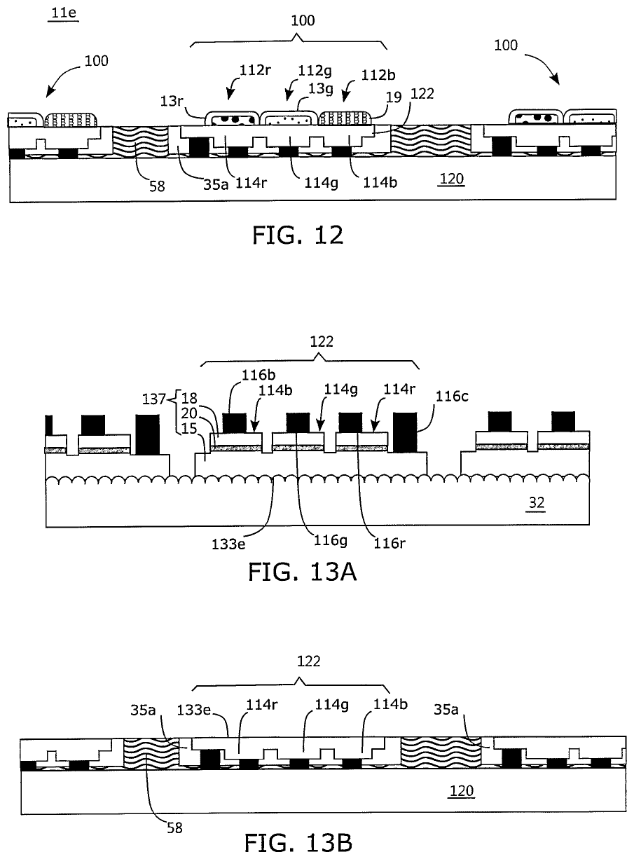

FIG. 12 illustrates a pixel module 11e according to one embodiment of the present disclosure, which includes a plurality of pixels 100 disposed on a driving carrier 120. The pixel 100 includes a red sub-pixel 112r, a green sub-pixel 112g, and a blue sub-pixel 112b driven by circuits on the driving carrier 120 to generate red light, green light, blue light, respectively. The pixel 100 in FIG. 12 includes a monolithic array chip (MAC) 122. As a light-emitting element, the monolithic array chip 122 has a plurality of light-emitting bodies 114r, 114g, 114b to emit lights with the same wavelength. The red sub-pixel 112r includes a wavelength conversion unit 13r and a light-emitting body 114r, the green sub-pixel 112g includes a wavelength conversion unit 13g and a light-emitting body 114g, and the blue sub-pixel 112b includes a filter layer 19 and a light-emitting body 114b. The monolithic array chip 122 is surrounded by a light reflecting layer 35a, and a light-shielding portion 58 is disposed on the driving carrier 120 and located between two adjacent monolithic array chips 122. The detailed description of other parts of the pixel 100 can be referred to FIGS. 1A, 1B and corresponding descriptions.

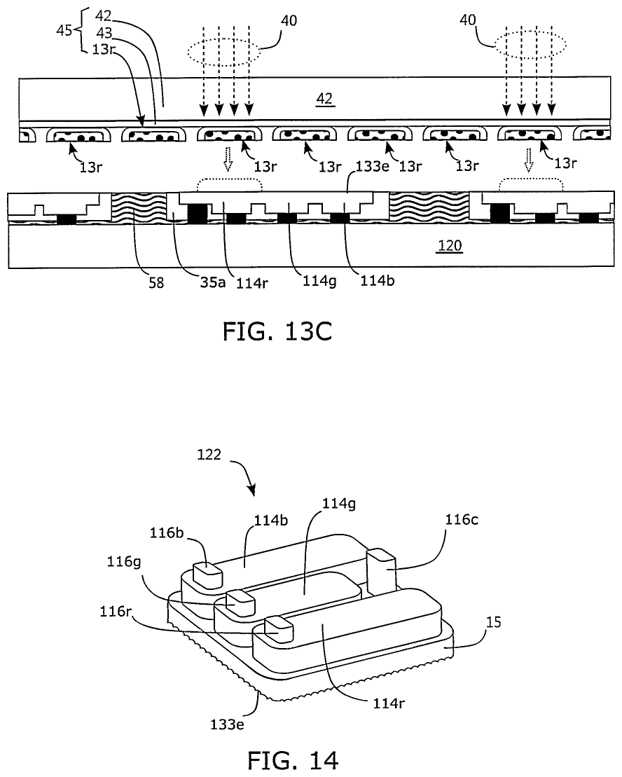

FIGS. 13A-13C illustrate a manufacturing process of a pixel module 11e shown in FIG. 12. As shown in FIG. 13A, the monolithic array chip 122 is located on the growth substrate 32 and has a first electrode 116r, a second electrode 116g, a third electrode 116b, and a common electrode 116c. A semiconductor stack 137 includes three light-emitting bodies 114r, 114g, 114b, and one of the light-emitting bodies 114r, 114g, and 114b includes a second semiconductor layer 18 and an active layer 20. Taking the light-emitting body 114r as an example, the first electrode 116r is electrically connected to the second semiconductor layer 18 of the light-emitting body 114r, and the common electrode 116c is electrically connected to the first semiconductor layer 15 of the semiconductor stack 137. By adjusting the current density flowing through the first electrode 116r and the common electrode 116c, the luminous intensity of the light-emitting body 114r can be controlled.

As shown in FIG. 13B, the light reflecting layer 35a and the light-shielding portion 58 surround the monolithic array chip 122. In one embodiment, the monolithic array chip 122 shown in FIG. 13A is transferred to the driving carrier 120 and then be surrounded by the light reflecting layer 35a and the light-shielding portion 58. The detailed description of the process of transferring the monolithic array chip 122 from the growth substrate 32 to the driving carrier 120 can be referred to FIG. 8A and corresponding descriptions. As shown in FIG. 13B, a light-exiting surface 133e of the monolithic array chip 122 is facing away from the driving carrier 120. In one embodiment, the monolithic array chip 122 is surrounded by the light-shielding portion 58 without any light reflecting layer (not shown).

As shown in FIG. 13C, the wavelength conversion unit 13r is irradiated by a laser light 40 and transferred to the light-exiting surface 133e. The wavelength conversion unit 13r is located on the light-exiting surface 133e to cover the light-emitting body 114r. In a plan view (not shown), the wavelength conversion unit 13r completely covers the light-emitting body 114r to prevent the light emitted by the light-emitting body 114r from leaking to other sub-pixels. The combination of the wavelength conversion unit 13r and the light-emitting body 114r can serve as the red sub-pixel 112r shown in FIG. 12. The detailed description of the structure and the manufacturing process of the green sub-pixel 112g and/or the blue sub-pixel 112b can be referred to the relevant drawings and descriptions of the red sub-pixel 112r.

FIG. 14 illustrates a schematic diagram of the monolithic array chip 122 in accordance with an embodiment of the present disclosure. The light-exiting surface 133e of the monolithic array chip 122 has a texture which is transferred from the growth substrate 32 shown in FIG. 13A. In one embodiment, the light-emitting bodies 114r, 114g, 114b of the monolithic array chip 122 have different sizes, and their relative positions can also be adjusted as needed.

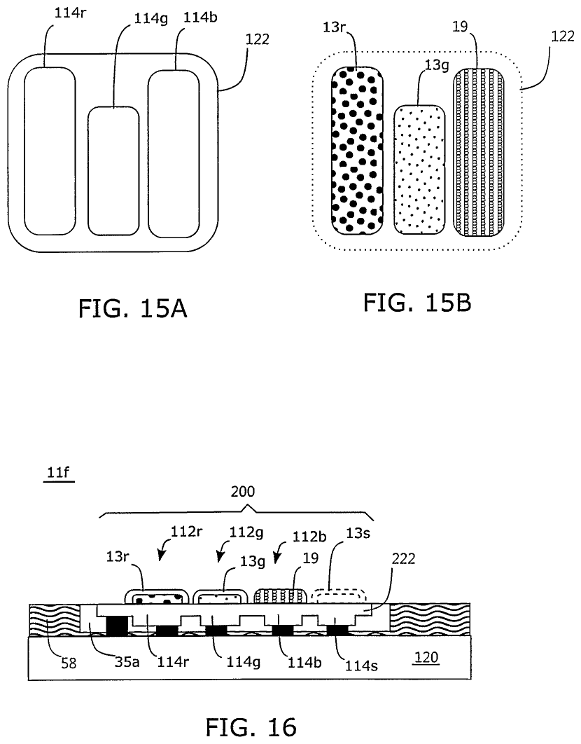

FIGS. 15A and 15B illustrate schematic diagrams of positions of the light-emitting bodies 114r, 114g, 114b of the monolithic array chip 122, and the relative positions of the wavelength conversion units 13r, 13g and the filter layer 19 on the monolithic array chip 122 in the pixel 100. FIG. 15A is a plan view of the monolithic array chip 122 as shown in FIG. 14 (for clarity, the first electrode 116r, the second electrode 116g, the third electrode 116b, and the common electrode 116c shown in FIG. 14 are omitted), FIG. 15B is a plan view of the wavelength conversion units 13r, 13g and filter layer 19 below the light-emitting bodies 114r, 114g, 114b as shown in FIG. 14 (for clarity, the monolithic array chip 122 is shown with dotted lines, and the light-emitting bodies 114r, 114g, 114b are omitted). Taking the light-emitting body 114r as an example, as shown in FIGS. 15A, 15B, the wavelength conversion unit 13r and the light-emitting body 114r have similar outer contours and are located at approximately the same projection position, and the wavelength conversion unit 13r completely covers the light-emitting body 114r.

FIG. 16 illustrates a pixel module 11f according to one embodiment of the present disclosure. The monolithic array chip in present disclosure is not limited to include only three light-emitting bodies. For example, a monolithic array chip 222 shown in FIG. 16 includes four light-emitting bodies 114r, 114g, 114b, 114s. In one embodiment, a pixel 200 shown in FIG. 16 includes a red sub-pixel 112r, a green sub-pixel 112g, and a blue sub-pixel 112b. If one of the red sub-pixel 112r, the green sub-pixel 112g, and the blue sub-pixel 112b is found to be operating abnormally (hereinafter referred to as a faulty sub-pixel) after testing, a repair process can be performed on the pixel module 11f shown in FIG. 16. The repair process includes causing the driving carrier 120 to no longer drive the light-emitting body of the faulty sub-pixel, but to drive the light-emitting body 114s of the pixel 200. In addition, according to the color of light that the faulty sub-pixel is supposed to emit, the corresponding wavelength conversion unit or the corresponding filter layer is transferred to the light-emitting body 114s to form a supplementary sub-pixel to replace the faulty sub-pixel. In one embodiment, the red sub-pixel 112r is determined to be a faulty sub-pixel after testing, the repair process can be performed so that the circuit on the driving carrier 120 stops driving the light-emitting body 114r and instead drives the light-emitting body 114s. In addition, one wavelength conversion unit 13r in the wavelength conversion unit arrangement 45 is transferred to the light-emitting body 114s to serve as a wavelength conversion unit 13s. Therefore, the light-emitting body 114s and the wavelength conversion unit 13s can replace the faulty sub-pixel 112r to complete the repair of the pixel 200. In one embodiment, if the green sub-pixel 112g is determined to be a faulty sub-pixel after testing, a repair process includes transferring a wavelength conversion unit 13g to the light-emitting body 114s to serve as the wavelength conversion unit 13s is performed. In one embodiment, if the blue sub-pixel 112b is determined to be a faulty sub-pixel, the wavelength conversion unit 13s during the repair process can be the filter layer 19. The detailed description of other parts of the pixel 200 can be referred to FIG. 12 and the relevant descriptions of the pixel 100.

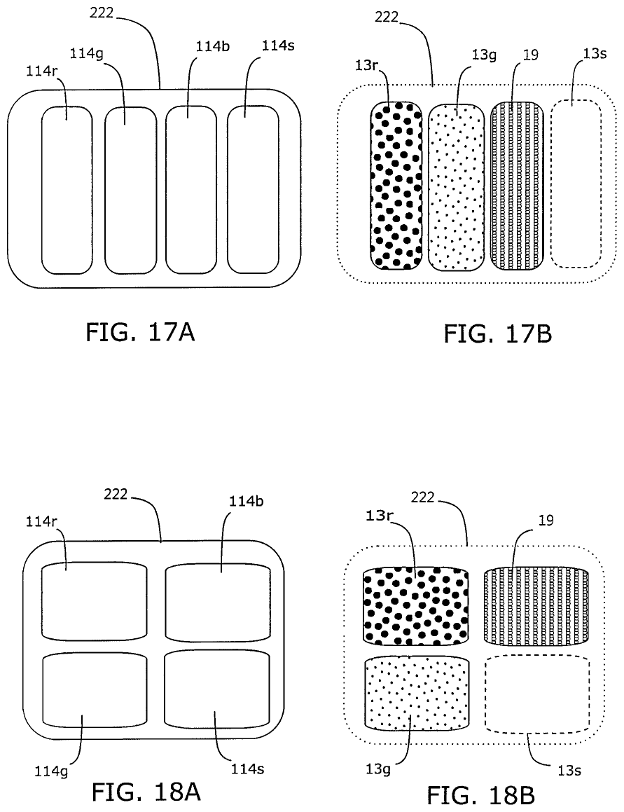

FIGS. 17A, 17B, 18A and 18B are schematic diagrams illustrating the relative positions of the light-emitting bodies and the wavelength conversion units in a pixel according to different embodiments of the present disclosure. In one embodiment, the relative positions of the light-emitting bodies 114r, 114g, 114b, 114s on the monolithic array chip 222 are shown in FIG. 17A, and the relative positions of the wavelength conversion units 13r, 13g, 13s and the filter layer 19 corresponding to the monolithic array chip 222 are shown in FIG. 17B. FIGS. 18A, 18B show the relative positions of the light-emitting bodies 114r, 114g, 114b, 114s of the monolithic array chip 222, and the positions of the corresponding wavelength conversion units 13r, 13g, 13s and the filter layer 19 projected on the monolithic array chip 222 in another embodiment. In one embodiment, the volume of the light-emitting body 114r is larger than that of the light-emitting bodies 114g and 114b, and is combined with a larger wavelength conversion unit 13r to generate more red light.

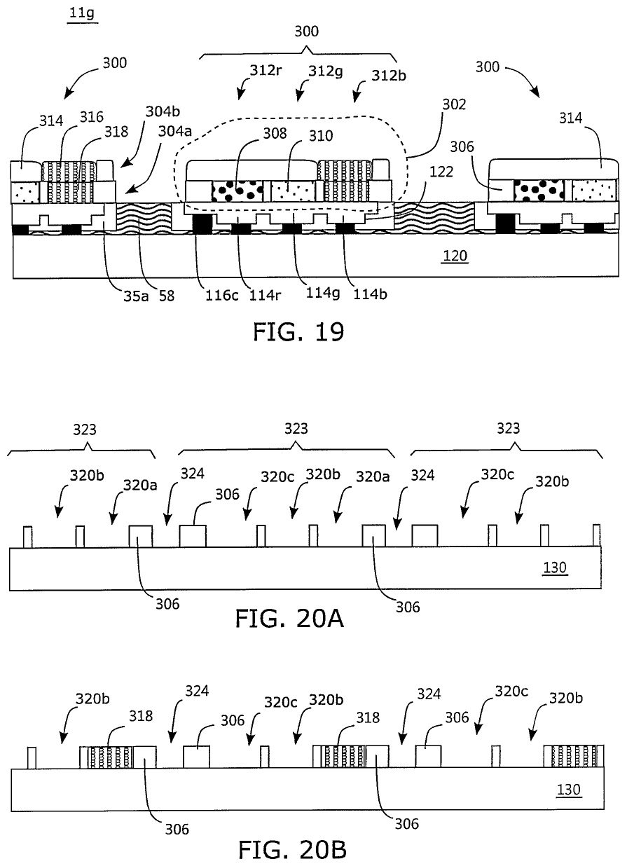

FIG. 19 shows a pixel module 11g according to one embodiment of the present disclosure. A pixel module 11g includes a plurality of pixels 300 and is located on a driving carrier 120. The pixel 300 includes a red sub-pixel 312r, a green sub-pixel 312g, and a blue sub-pixel 312b driven by circuits on the driving carrier 120 to generate red light, green light and blue light, respectively. An optical set 302 is disposed on the monolithic array chip 122. The optical set 302 includes two structural layers 304a, 304b in stacked. The structural layer 304a includes a light-blocking layer 306, a wavelength conversion layer 308, a wavelength conversion layer 310, and a filter layer 318. The structural layer 304b is formed on the structural layer 304a, and includes a filter layer 314 and a filter layer 316. The detailed description of other parts of the pixel 300 can be referred to FIG. 12 and the relevant descriptions of the pixel 100.

In one embodiment, the material and manufacturing process of the wavelength conversion layer 308 can refer to the aforementioned wavelength conversion layer 22. The material and manufacturing process of the wavelength conversion layer 310 can refer to the wavelength conversion layer in the wavelength conversion unit 13g. The material and manufacturing process of the filter layer 314 can refer to the filter layer 24 in the wavelength conversion unit 13r. In one embodiment, the filter layer 316 and the filter layer 318 are made of the same material, and their manufacturing process can refer to the relevant descriptions of the filter layer 19. In one embodiment, the material composition of filter layers 316 and 318 are different from the material composition of filter layer 314. The light-blocking layer 306 can prevent color interference between sub-pixels. In one embodiment, the light-blocking layer 306 has a black appearance.

In one embodiment, the wavelength conversion layers 308, 310, the filter layers 314, 316, 318, and the light-blocking layer 306 all include at least one of propylene glycol monomethyl ether acetate (PGMEA), acrylic monomer, and acrylic resin.

As shown in FIG. 19, the optical set 302 includes a sub-stack structure, including a wavelength conversion layer 308 and a filter layer 314, to cover the light-emitting body 114r to form a red sub-pixel 312r. The optical set 302 includes a sub-stack structure, including a wavelength conversion layer 310 and a filter layer 314, to cover the light-emitting body 114g to form a green sub-pixel 312g. The optical set 302 includes a sub-stack structure, including a filter layer 316 and a filter layer 318 (wherein the filter layers 316, 318 may be formed of the same material), to cover the light-emitting body 114b to form a blue sub-pixel 312b.

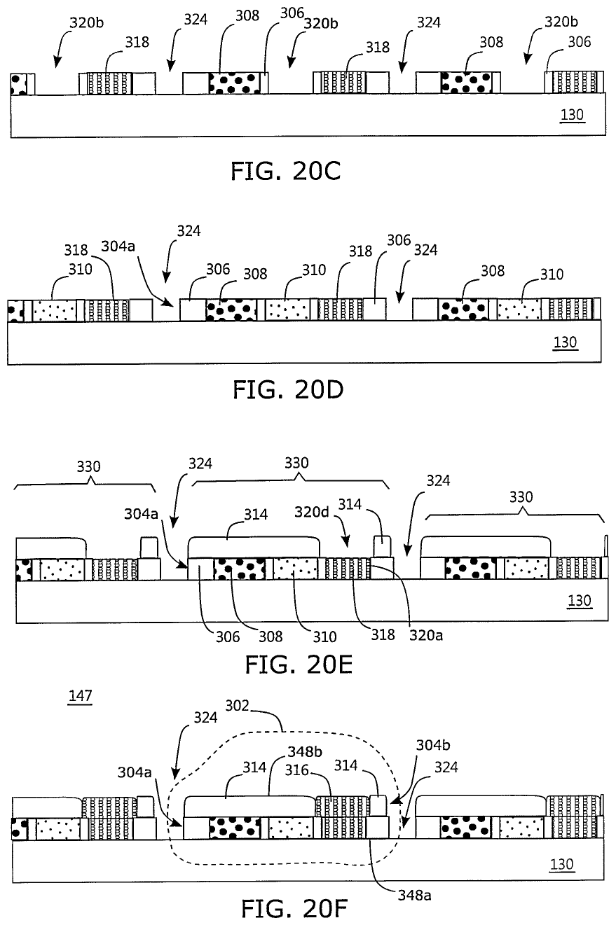

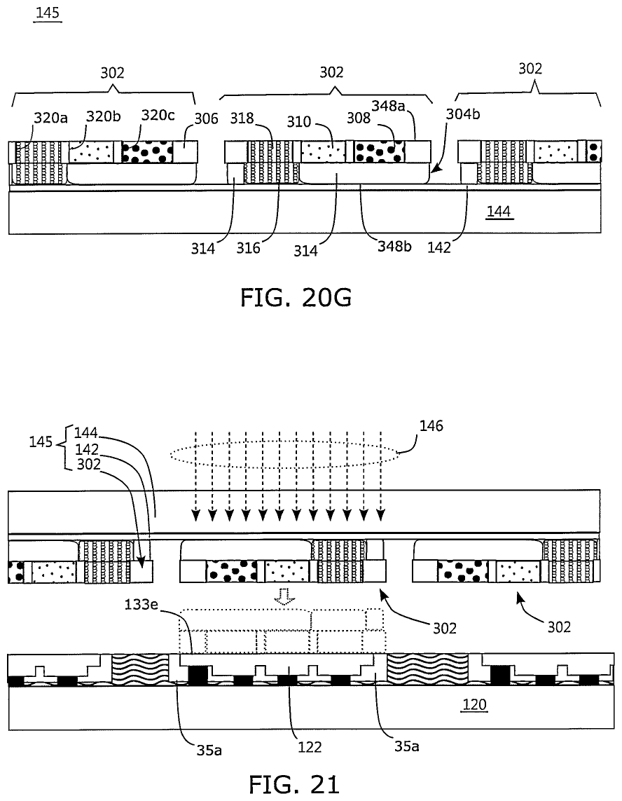

In one embodiment, the wavelength conversion layers 308 and 310, the filter layers 314, 316, 318, and the light-blocking layer 306 in the optical set 302 all include photosensitive materials (such as photoresist) and are suitable for being formed through a photolithography process. FIGS. 20A-20G illustrate a manufacturing process of the optical set 302 according to an embodiment of the present disclosure. FIG. 20A shows a light-blocking layer 306 formed on a carrier 130. The carrier 130 can be a sapphire substrate, quartz substrate or glass substrate. The light-blocking layer 306 is formed on the carrier 130 and has a plurality of patterns 323 separated by separation areas 324. one pattern 323 has a plurality of holes 320a, 320b, 320c, as shown in FIG. 20A. In one embodiment, a distance between two adjacent holes 320a, 320b, and 320c in the pattern 323 is equal to or less than 5 μm, such as 3 μm or 1 μm. In one embodiment, the thickness of the light-blocking layer 306 is equal to or less than 2 μm, such as 1 μm.

Then, a filter layer 318 is formed in the hole 320a (FIG. 20B), a wavelength conversion layer 308 is formed in the hole 320c (FIG. 20C), and a wavelength conversion layer 310 is formed in the hole 320b (FIG. 20D) in sequence to form the structural layer 304a. The filter layer 318, the wavelength conversion layer 308 and/or the wavelength conversion layer 310 can selectively fulfill into the corresponding holes 320a, 320c, 320b. In one embodiment, the filter layer 318, the wavelength conversion layer 308, the wavelength conversion layer 310, and the light-blocking layer 306 have approximately the same thickness, so that the upper surface of the filter layer 318, the upper surface of the wavelength conversion layer 308, the upper surface of the wavelength conversion layer 310, and the upper surface of the light-blocking layer 306 are substantially coplanar. In another embodiment, at least one of the filter layer 318, the wavelength conversion layer 308, and the wavelength conversion layer 310 has a thickness lower than that of the light-blocking layer 306. The formation order of the filter layer 318, the wavelength conversion layer 308, and the wavelength conversion layer 310 can be adjusted. For example, the wavelength conversion layer 308, the filter layer 318, and the wavelength conversion layer 310 are formed in sequence.

As shown in FIG. 20E, a filter layer 314 is formed on the structural layer 304a shown in FIG. 20D. The filter layer 314 has a pattern 330, wherein the pattern 330 has a hole 320d. The hole 320d can fully or partially expose the upper surface of the filter layer 318. In one embodiment, the boundary of the hole 320d is larger than the edge of the filter layer 318, as shown in FIG. 20E. In one embodiment, the thickness of the filter layer 314 is equal to or less than 2.5 μm, such as 2 μm.

As shown in FIG. 20F, a filter layer 316 is formed in the hole 320d to form the structural layer 304b. The filter layer 316 can fill the hole 320d fully or partially. By sequentially stacking the structural layers 304a and 304b, the optical set 302 and a wavelength conversion unit arrangement 147 which includes the optical set 302 and the carrier 130 are formed, wherein the optical set 302 has two surfaces 348a, 348b facing different directions.

As shown in FIG. 20G, the optical set 302 shown in FIG. 20F is turned upside down and then transferred to an adhesive layer 142 on a carrier 144. In one embodiment, a laser light is used to illuminate the surface 348a shown in FIG. 20F to dissociate the material of the surface 348a. The detailed description of the laser dissociation process can be referred to FIG. 9 and corresponding descriptions. The optical set 302 is separated from the carrier 130 and adhered to the carrier 144 through the surface 348b to form a wavelength conversion unit arrangement 145. Because the surface 348a is formed by laser decomposition, the texture of the surface 348a can be different from that of the surface 348b. In one embodiment, the profile of the surface 348a can be referred to the position of the wavelength conversion unit 13r in FIG. 7B, and the profile of the surface 348b can be referred to the position of the wavelength conversion unit 13r in FIG. 7A.

As shown in FIG. 21, at least one optical set 302 is selectively irradiated by a laser light 146 to cause structure changes in the corresponding adhesive layer 142, thereby allowing the irradiated optical set 302 to be transferred to the monolithic array chip 122. In one embodiment, an adhesive layer can be pre-disposed on the monolithic array chip 122 and/or the light reflecting layer 35a to fix and cover the optical set 302 on the light-exiting surface 133e of the monolithic array chip 122. The pixel module 11g as shown in FIG. 19 can be formed by placing the optical set 302 on the corresponding light-exiting surface 133e as shown in FIG. 21.

As shown in FIGS. 20G, 21, a group including the carrier 144, the adhesive layer 142 and the optical set 302 can be regarded as the wavelength conversion unit arrangement 145. The optical set 302 in the wavelength conversion unit arrangement 145 can be transferred to the monolithic array chip 122 through at least one transfer process (such as laser irradiation to dissociate the adhesive layer 142 at the corresponding position). As shown in FIG. 20G, in the optical set 302, the light-blocking layer 306 has a plurality of holes 320a, 320b, 320c, wherein the filter layer 318, the wavelength conversion layer 308, and the wavelength conversion layer 308 are respectively arranged in the holes. The filter layer 316 is located between the carrier 144 and the filter layer 318. The filter layer 314 is located between the wavelength conversion layer 310 and the carrier 144, and also between the wavelength conversion layer 308 and the carrier 144.

In another embodiment, the driving carrier 120 in FIG. 21 can be replaced by a temporary carrier (not shown), and the monolithic array chip 122 and the corresponding optical set 302 can be transferred to the temporary carrier through an adhesive layer (not shown). According to subsequent applications, both the monolithic array chip 122 and the optical set 302 are transferred to a target substrate.

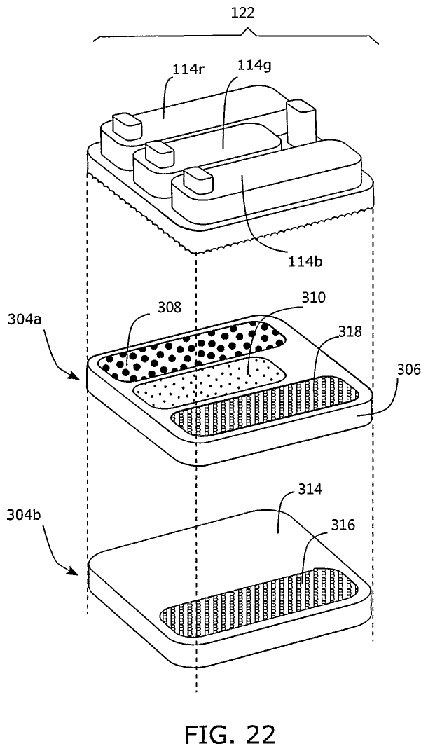

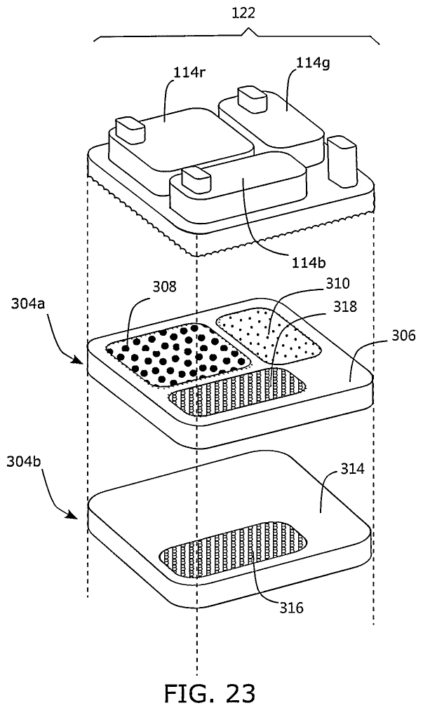

FIGS. 22-24 show exploded views of a monolithic array chip and an optical set in different embodiments of the present disclosure to illustrate the relative positions of the monolithic array chip 122, and the structural layer 304a and the structural layer 304b in the optical set 302. At least one of the light-emitting bodies 114r, 114g, 114b is different in position, size, and/or shape as shown between FIGS. 22, 23. As shown in FIGS. 22, 23, the positions of the wavelength conversion layers 308, 310 and the filter layer 318 in the structural layer 304a are approximately aligned with the light-emitting bodies 114r, 114g, 114b respectively, and the position of the filter layer 316 in the structural layer 304b is approximately aligned with the light-emitting body 114b.

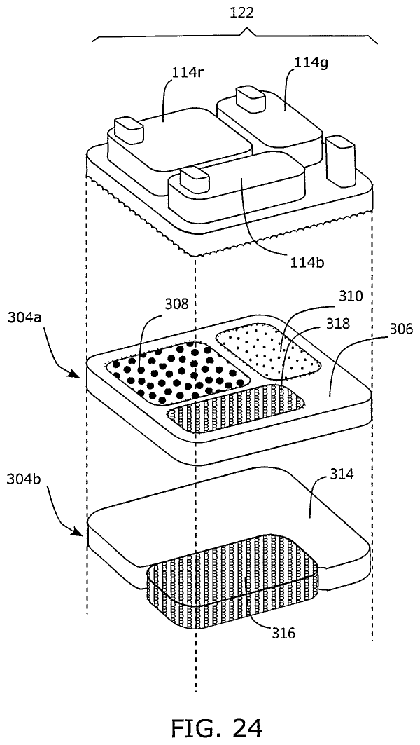

The filter layer 314 surrounds the filter layer 316 as shown in FIG. 23, but does not surround the filter layer 316 as shown in FIG. 24. In one embodiment, the filter layer 314 has a hole (as shown in FIG. 23) for the filter layer 316 to be formed therein. In another embodiment, the filter layer 314 does not have any hole (as shown in FIG. 24), the filter layer 316 and the filter layer 314 are arranged side by side on the same plane, wherein the filter layer 316 can be attached to the side of the filter layer 314. Compared with the structural layer 304b shown in FIG. 24, the structural layer 304b shown in FIG. 23 provides a relatively flat exposed surface of the optical set 302, which allows the optical set 302 to be stably fixed on the carrier 144 during the transfer process as shown from FIG. 20F to FIG. 20G.

The projected areas of the wavelength conversion layers 308, 310 and the filter layer 318 can be greater than, equal to, or smaller than the projected areas of the corresponding light-emitting bodies 114r, 114g, 114b, and are located at the corresponding positions of the light-emitting bodies 114r, 114g, 114b in a plan view. In one embodiment, the projected areas of the wavelength conversion layers 308, 310 and the filter layer 318 are slightly smaller than that of the corresponding light-emitting bodies 114r, 114g, 114b to prevent the wavelength conversion layers 308, 310 and the filter layer 318 from not being completely located on the corresponding light-emitting bodies 114r, 114g, 114b. In one embodiment, the projected area of the light-emitting body 114r is greater than that of the light-emitting bodies 114g, 114b to overcome the color shift problem of poor conversion efficiency of the red wavelength conversion layer 308. In another embodiment, the light-emitting bodies 114r, 114g, 114b have the same size projected area. By adjusting the projected areas of the wavelength conversion layers 308, 310 and the filter layer 318 (or the size of the holes 320a, 320b, 320c shown in FIG. 20A), the color and light intensity of the monolithic array chip 122 combined with the optical set 302 can be adjusted.

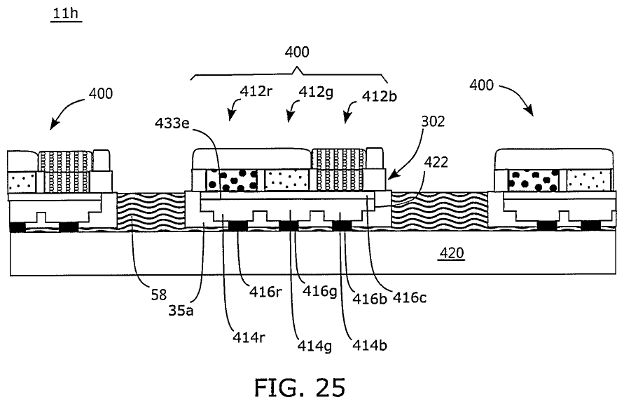

FIG. 25 shows a pixel module 11h according to one embodiment of the present disclosure, which has a plurality of pixels 400 arranged on a driving carrier 420. One pixel 400 has a red sub-pixel 412r, a green sub-pixel 412g, and a blue sub-pixel 412b driven by circuits on the pixel 400 to generate three primary colors of light: red light, green light, and blue light. A monolithic array chip 422 includes light-emitting bodies 414r, 414g, 414b, and the optical set 302 is disposed on the monolithic array chip 422.

As shown in FIG. 25, a first electrode 416r, a second electrode 416g, and a third electrode 416b of the monolithic array chip 422 are on the same side facing the driving carrier 420, but a common electrode 416c is on the side away from and connected to the driving carrier 420 through a conductive structure (not shown). The common electrode 416c includes a transparent conductive material, such as indium tin oxide (ITO). The optical set 302 is disposed on the common electrode 416c, and the common electrode 416c is formed on a light-exiting surface 433e. The detailed description of other parts of the pixel 400 can be referred to FIG. 19 and the corresponding descriptions of the pixel 300.

In some embodiments, the optical set 302 is not combined with a monolithic array chip. For example, the monolithic array chip 122, 422 in FIGS. 19, 25 can be replaced by three light-emitting elements 41 as shown in FIG. 5C.

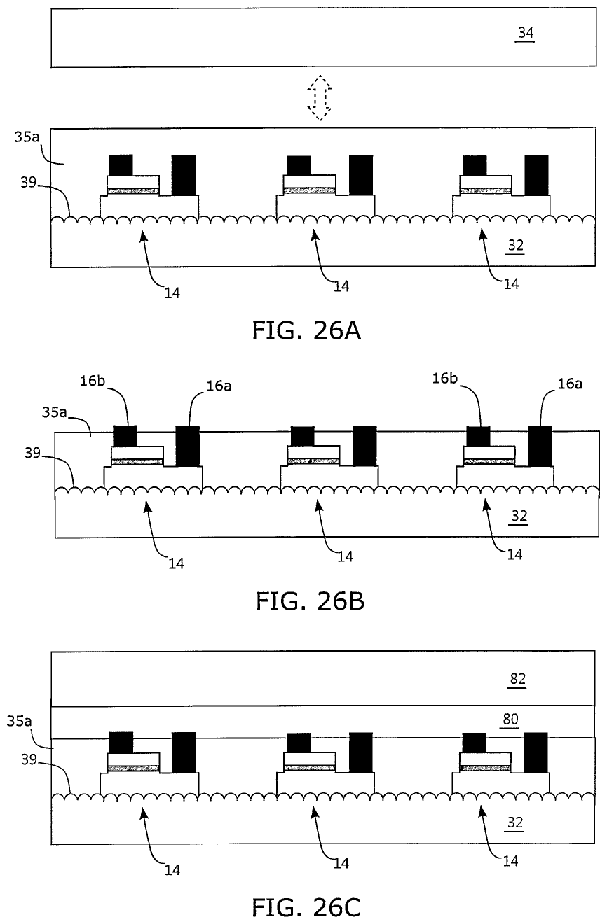

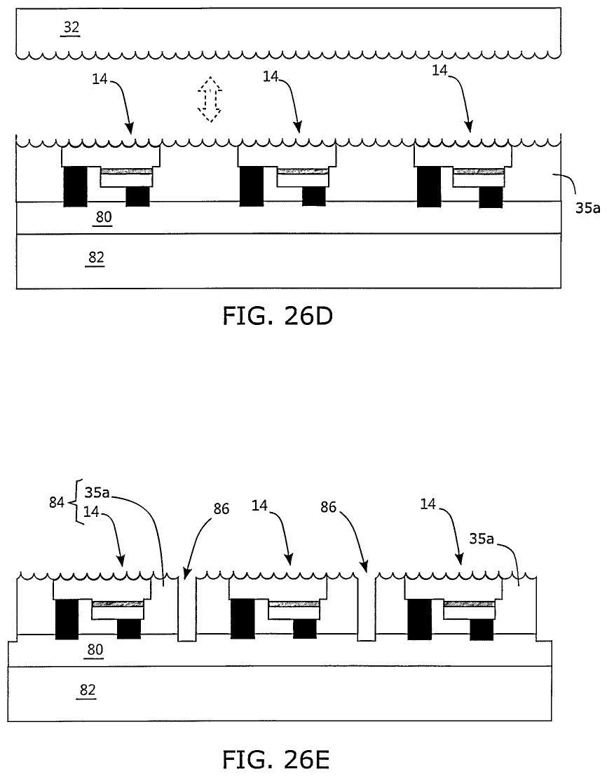

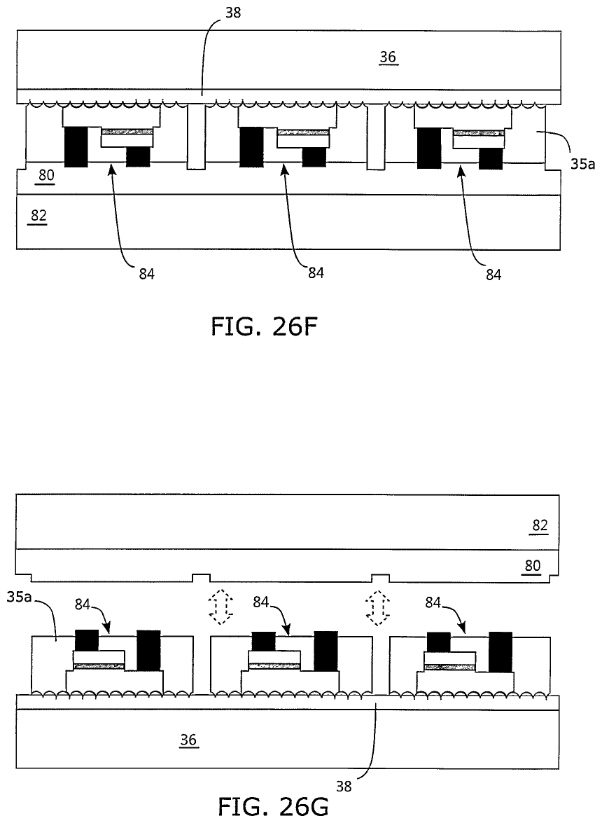

FIGS. 26A-26G illustrate a manufacturing process of a light-emitting element 41 shown in FIG. 5C in accordance with one embodiment of the present disclosure. In one embodiment, the structure shown in FIG. 26A is formed after the structure shown in FIG. 2B. As shown in FIG. 26A, the carrier 34 is separated from the light reflecting layer 35a by a laser de-bonding process, wherein the LED chip 14 is located between the light reflecting layer 35a and the growth substrate 32. Then, the light reflecting layer 35a is thinned as shown in FIG. 26B. In one embodiment, the light reflecting layer 35a is thinned by a dry etching process (such as ICP process) until the electrodes 16a, 16b are exposed.

As shown in FIG. 26C, a carrier 82 with an adhesive layer 80 is attached to the LED chip 14 and the light reflecting layer 35a. In one embodiment, the adhesive layer 80 is a laser de-bonding layer, such as a layer including an acrylic based material. The carrier 82 can be penetrated by a laser light, wherein the carrier 82 is, for example, a sapphire substrate or a glass substrate. In one embodiment, the adhesive layer 80 is formed on the carrier 82, and then the carrier 82 and the adhesive layer 80 are covered on the LED chip 14 shown in FIG. 26B to form a structure as shown in FIG. 26C. After that, the growth substrate 32 is peeled off from the LED chip 14 and the light reflecting layer 35a, as shown in FIG. 26D. In one embodiment, the growth substrate 32 is peeled off from the LED chip 14 and the light reflecting layer 35a by a laser lift-off (LLO) process.

As shown in FIG. 26E, portions of the light reflecting layer 35a between two adjacent LED chips 14 are removed to form a plurality of light-emitting elements 84 on the carrier 82. The light-emitting element 84 includes the LED chip 14 and the light reflecting layer 35a. In one embodiment, a patterned mask is formed on the light reflecting layer 35a, and then the light reflecting layer 35a is etched by an ICP process to form an isolation channel 86. In another embodiment, a portion of the light reflecting layer 35a is directly removed by irradiating a laser light to form the isolation channel 86. In one embodiment, a portion of the adhesive layer 80 is also removed during forming the isolation channel 86, as shown in FIG. 26E. In one embodiment, a wavelength conversion unit (not shown) is formed above the light-emitting element 84 to form a component which is similar to the light-emitting component 29b shown in FIG. 3D.

As shown in FIG. 26F, a carrier 36 is attached to the light-emitting element 84 through an adhesive layer 38. Then, the adhesive layer 80 is separated from the light-emitting element 84, as shown in FIG. 26G. In one embodiment, the adhesive layer 80 and the light-emitting element 84 are separated by a laser separation process. In one embodiment, the appearance of the adhesive layer 80 changes after being irradiated by a laser light, thereby reducing the ability of the adhesive layer 80 to capture the light-emitting element 84. In another embodiment, the adhesive layer 80 is dissociated after being irradiated by a laser light, thereby reducing the ability of the adhesive layer 80 to capture the light-emitting element 84. The detailed description of the light-emitting element 84 can be referred to the light-emitting element 41 in FIG. 5C and corresponding descriptions.

In one embodiment, a weakening process (such as irradiating a UV light to the adhesive layer 80) is performed during the transition from the structure shown in FIG. 26C to the structure shown in FIG. 26G. The weakening process can reduce the adhesive force between the adhesive layer 80 and the light-emitting element 84, thereby improving the separation yield of the laser separation process shown in FIG. 26G.

Although some embodiments of the present disclosure and their advantages have been described in detail, various changes, substitutions and alterations may be made herein without departing from the spirit and scope of the disclosure as defined by the appended claims.

What is claimed is:

1. A wavelength conversion unit arrangement, comprising:
a carrier; and
a wavelength conversion unit, comprising a first wavelength conversion layer and a filter layer, the wavelength conversion unit being attached to the carrier by the filter layer, the filter layer having a first surface facing the carrier and a second surface facing away from the carrier;
wherein the first surface and the second surface have different textures.

2. The wavelength conversion unit arrangement according to claim 1, wherein the first surface directly contacts the carrier, the wavelength conversion unit is capable to be separated from the carrier by laser irradiation, and the first surface after separation from the carrier and the second surface before separation from the carrier have different textures.

3. The wavelength conversion unit arrangement according to claim 1, wherein the wavelength conversion unit further comprises a light-blocking layer, the light-blocking layer has a first hole and a second hole, the first wavelength conversion layer is located in the first hole, and the filter layer is located in the second hole.

4. The wavelength conversion unit arrangement according to claim 3, wherein the filter layer further comprises a first filter layer and a second filter layer, the first filter layer is located in the second hole, and the second filter layer covers the first wavelength conversion layer.

5. The wavelength conversion unit arrangement according to claim 4, wherein the second filter layer surrounds the second hole.

6. The wavelength conversion unit arrangement according to claim 4, wherein the light-blocking layer has a third hole, the wavelength conversion unit further comprises a second wavelength conversion layer, and the second filter layer covers the second wavelength conversion layer.

7. The wavelength conversion unit arrangement according to claim 1, wherein the filter layer comprises a first filter layer, a second filter layer, and a third filter layer, the first filter layer is covered by the third filter layer, and the first wavelength conversion layer is covered by the second filter layer.

8. The wavelength conversion unit arrangement according to claim 7, wherein the wavelength conversion unit comprises a light-blocking layer surrounding the first filter layer and the first wavelength conversion layer.

9. The wavelength conversion unit arrangement according to claim 8, wherein the second filter layer and the third filter layer cover the light-blocking layer.

10. A method of manufacturing a pixel module, comprising:
providing a light-emitting element, the light-emitting element having a light-exiting surface;
providing a wavelength conversion unit arrangement, the wavelength conversion unit arrangement comprising a carrier and a wavelength conversion unit arranged on the carrier, the wavelength conversion unit comprising a first wavelength conversion layer and a filter layer, and the filter layer having a first surface facing the carrier and a second surface facing away from the carrier; and
transferring the wavelength conversion unit to the light-exiting surface and exposing the first surface;
wherein the first surface after the transferring step and the second surface before the transferring step have different textures.

11. The method of claim 10, further comprising:
forming the filter layer and the first wavelength conversion layer sequentially on the carrier to form the wavelength conversion unit;
wherein, in a plan view, the filter layer has an edge surrounding the first wavelength conversion layer.

12. The method of claim 10, wherein the transferring step further comprises separating the filter layer from the carrier by laser irradiation.

13. The method of claim 10, wherein the carrier is a first carrier, and the method further comprises:
forming the first wavelength conversion layer and the filter layer sequentially on a second carrier to form the wavelength conversion unit; and
transferring the wavelength conversion unit from the second carrier to the first carrier.

14. The method of claim 13, wherein the step of transferring the wavelength conversion unit to the first carrier further comprises separating the wavelength conversion unit from the second carrier by laser irradiation.

15. The method of claim 10, wherein the light-emitting element has a first light-emitting body and a second light-emitting body, and the wavelength conversion unit further comprises a second wavelength conversion layer, after the transferring step, the first wavelength conversion layer covers the first light-emitting body and the second wavelength conversion layer covers the second light-emitting body.

16. The method of claim 15, wherein the wavelength conversion unit further comprises a light-blocking layer surrounding the first wavelength conversion layer and the second wavelength conversion layer.

17. A light-emitting component, comprising:
a chip, having a light-exiting surface; and
a light reflecting layer, surrounding the chip and exposing the light-exiting surface;
wherein the light reflecting layer has an upper surface, and the upper surface has a texture extending from the light-exiting surface.

18. The light-emitting component according to claim 17, wherein the upper surface is coplanar with the light-exiting surface.

19. The light-emitting component according to claim 17, further comprising a first wavelength conversion layer covering the upper surface and the light-exiting surface.

20. The light-emitting component according to claim 19, wherein the first wavelength conversion layer fills the texture.
